(19) United States
(12) Patent Application Publication
(10) Pub. No.: US 2010/0244675 A1
(43) Pub. Date: Sep. 30, 2010

(54) ORGANOMETALLIC COMPLEX AND ORGANIC LIGHT-EMITTING DIODE INCLUDING THE SAME

(75) Inventors: Chien-Hong CHENG, Hsinchu (TW); Chun-Hsiang FAN, Hsinchu (TW)

Correspondence Address: PAI PATENT & TRADEMARK LAW FIRM, 1001 FOURTH AVENUE, SUITE 3200, SEATTLE, WA, 98154, US

(73) Assignee: Chien-Hong Cheng, Hsinchu (TW)

(21) Appl. No.: 12/750,690

(22) Filed: Mar. 30, 2010

(30) Foreign Application Priority Data
Mar. 31, 2009 (TW) 098110608

(51) Int. Cl. H01L 51/54; C07F 15/00

(52) U.S. Cl. 313/504; 544/225; 546/4

(57) ABSTRACT

The invention provides an organometallic complex having Formula (I):

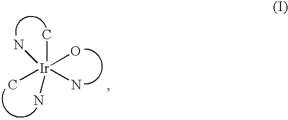

wherein each of N̂C bidentate ligands independently is:

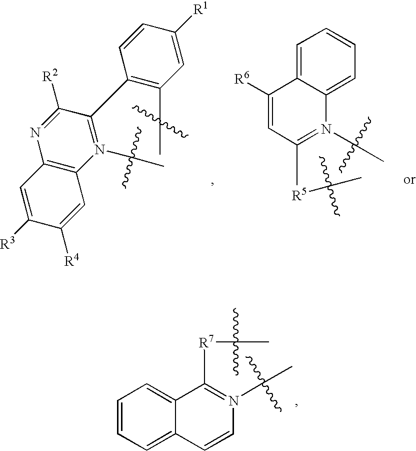

an N̂O bidentate ligand is:

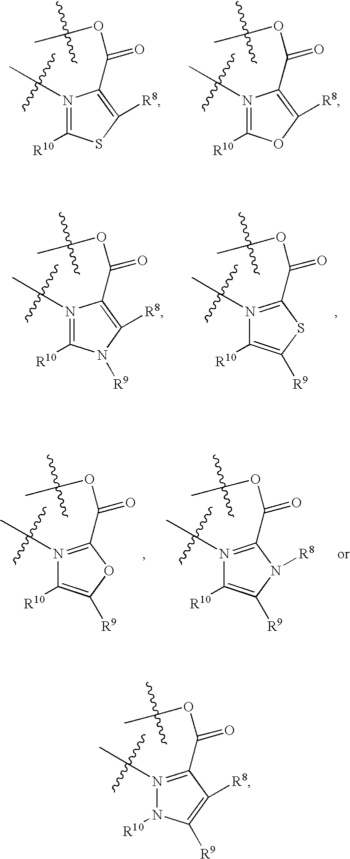

R¹ to R¹⁰ each independently are H, alkyl, alkenyl, alkynyl, CN, CF₃, alkylamino, amino, alkoxy, halo, aryl, or heteroaryl.

### CROSS REFERENCE TO RELATED APPLICATIONS

This Application claims priority of Taiwan Patent Application No. 98110608, filed on Mar. 31, 2009, the entirety of which is incorporated by reference herein.

### BACKGROUND OF THE INVENTION

1. Field of the Invention

The present invention relates to a light-emission material and an organic light-emitting diode including the same.

2. Description of the Related Art

An organic light-emitting diode (OLED) (also referred to as organic electroluminescent device) is an LED with an organic layer serving as an active layer. OLEDs have been increasingly applied in flat panel displays due to advantages over other LEDs such as low voltage operation, high brightness, light weight, slim profile, wide viewing angle, and highly effective contrast ratio. The OLED is self-emitting and highly luminous, with wide viewing angles, fast response speeds, and a simple fabrication method.

Generally, OLEDs are composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and the electron, the exciton which results from recombination of the hole and the electron can have either a triplet or singlet spin state. Luminescence from a singlet exciton results in fluorescence whereas luminescence from a triplet exciton results in phosphorescence. The emissive efficiency of phosphorescence is three times that of fluorescence. Therefore, it is crucial to develop highly efficient phosphorescent material, in order to increase the emissive efficiency of the OLED.

Applications regarding organometallic complexes used in organic electroluminescent devices began in 1980, such as Pt(II), Ru(II), Os(II), Eu(III), and Ir(III) complexes, of which Ir(III) complexes were the most popular.

Initial doped red phosphorescent complexes were provided by M. E. Thompson and S. R. Forest as disclosed in Nature, 395, 1988, pages 151˜154, providing Pt as a metal center of a complex with a luminescent wavelength of 650 nm, quantum efficiency of 1.3%, and luminescent intensity of 0.151 m/W under a current density of 100 cd/A. More types of Jr complexes were provided by M. E. Thompson in 2001 (J. Am. Chem. Soc. 2001, 123, 4304-4312), with luminescent wavelengths across red, green, and blue light regions. In 2003, M. E. Thompson further provided a comparison of luminescent efficiency and lifetime between facial and meridional isomers of a Jr complex as disclosed in J. Am. Chem. Soc. 2003, 125, 7377-7387. Other related technology is disclosed in U.S. Pre-Grant Pat. No. 2002024293, 2002034656, 2002045061, 2003017361, 2003092935, 2003102800, 2004053071, 2004102632, 2004086743, and 2004110031, in J.P. Pre-Grant Pat. No. 2002226495, 2002338588, 2003109758, 2003113246, 2003119179, 2003123982, 2003147021, 2003171391, 2003206320, 2003253128, 2003253129, 2003253145, and 2004111379, and in G.P Pre-Grant Pat. No. 2004026886, 2004028217, 2004037836, 2004048395, and 2004055130.

Various Jr complexes have been provided, such as Jr complexes coordinating with acetyl acetone as disclosed in E.P. Pat. No. 1434286 and a blue phosphorescent Jr complex with an emission wavelength exceeding 500 nm and quantum efficiency exceeding 5% as disclosed in U.S. Pat. No. 2002024293. Orange phosphorescent Ir complexes, however, have yet to be effectively provided, regarding compounds such as Bt₂Ir(acac) with an emission wavelength of about 560 nm provided by Thompson as disclosed in J. Am. Chem. Soc. 2001, 123, 4304-4312 and an orange phosphorescent Ir complex with emission wavelength of about 570 nm as disclosed in G.P. Pat. No. 2003040250.

### BRIEF SUMMARY OF INVENTION

A detailed description is given in the following embodiments with reference to the accompanying drawings.

The invention provides an organometallic complex, having Formula (I):

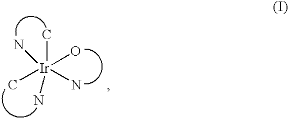

wherein each of N̂C bidentate ligands independently is:

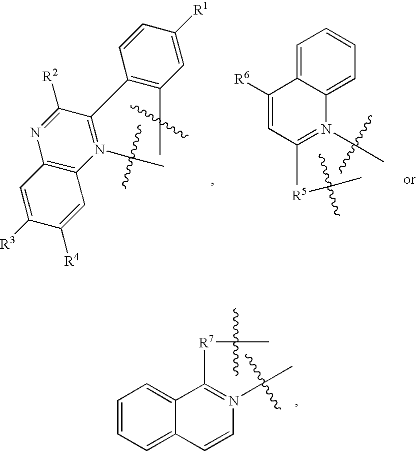

an N̂O bidentate ligand is:

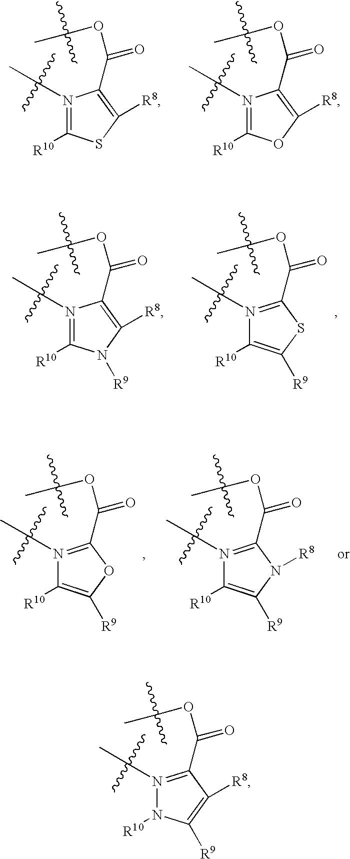

R¹ to R¹⁰ each independently are H, alkyl, alkenyl, alkynyl, CN, CF₃, alkylamino, amino, alkoxy, halo, aryl, or heteroaryl.

The invention provides an organic light-emitting diode. A light-emission layer including the organometallic complex having Formula (I) is disposed between a cathode and anode.

### BRIEF DESCRIPTION OF DRAWINGS

The present invention can be more fully understood by reading the subsequent detailed description and examples with references made to the accompanying drawings, wherein:

FIGS. 1 to 4 show organic light-emitting diodes according to embodiments of the present invention.

FIGS. 5-1 to 5-13 show spectrograms of the UV absorption and PL of the complexes of the embodiments of the present invention.

FIGS. 6-1 to 9-2 show PL spectrograms of the light-emitting devices of the embodiments of the present invention.

### DETAILED DESCRIPTION OF INVENTION

Controlling light colors of red phosphorescent complexes used for light-emitting diodes is a challenge. Emitting efficiency from saturated red light to deep red light of red phosphorescent complexes having a small light-emitting energy gap and influenced with the energy gap low can not be improved. Some possible potential deep-red phosphorescent materials having a small light-emitting energy gap would cause a low efficiency and lifetime of a device, and thus is not suitable in practical utility. A red phosphorescent material having ancillary ligands used for adjusting wavelength of emitting light may have the emitting light of a widened full width half maximum (FWHM) because of ligand to ligand charge transfer (or linter-ligand charge transfer) and non-radiative energy transfer. Therefore color purity, power efficiency, current efficiency and quantum efficiency of a light-emitting diode is dramatically reduced. Embodiments of present invention provides a red phosphorescent material comprising a red phosphorescent organometallic complex having an N̂O bidentate ligand. The color of the emitting light from the red phosphorescent organometallic complex can be adjust by the N̂O bidentate ligand. The FWHM of the emitting light is also decreased. Therefore, a device having the red phosphorescent organometallic complex has an improved color purity and efficiency.

The present invention provides an organometallic complex, having Formula (I):

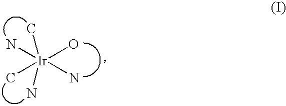

wherein each of N̂C bidentate ligands independently is:

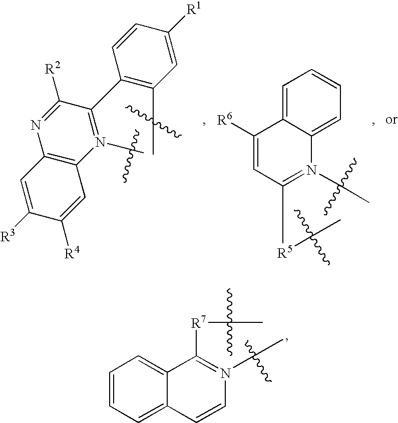

an N̂O bidentate ligand is:

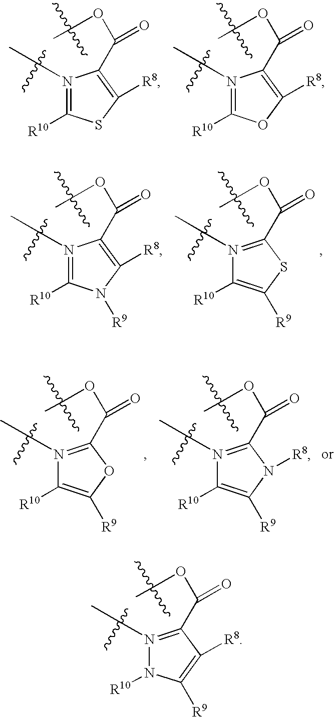

R¹ to R¹⁰ each independently are H, alkyl, alkenyl, alkynyl, CN, CF₃, alkylamino, amino, alkoxy, halo, aryl, or heteroaryl. R¹ preferably is H or F. R³ and R⁴ preferably are the same.

The stability of the complex can be improved as R² is alkyl. The emitting light from the complex exhibits a blue shift as R³ and R⁴ are alkyl, and thus a power efficiency of a device comprising the complex is increased. The emitting light from the complex exhibits a red shift as R³ and R⁴ are fluorine of halogen, and thus a saturation degree of an emitting light from a device comprising the complex is increased. In addition, the complex would have a good stability as it is formed by a vacuum deposition.

In some specific embodiments, the N̂C bidentate ligands are the same, and include the following:

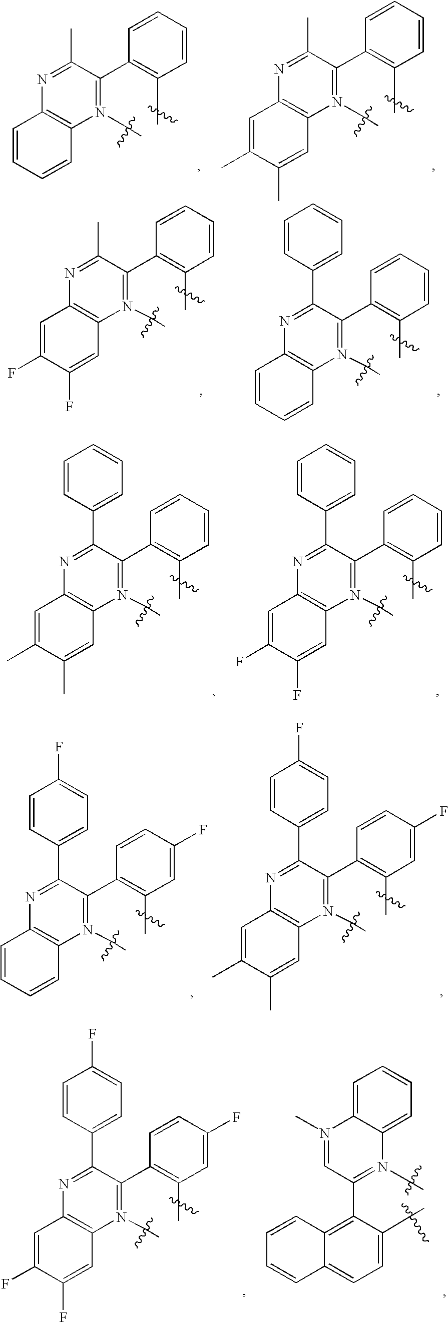

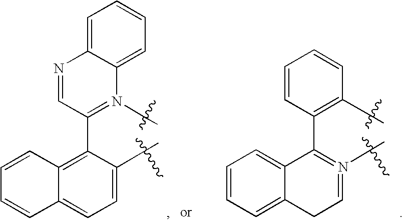

In some specific embodiments, the N̂O bidentate ligand is:

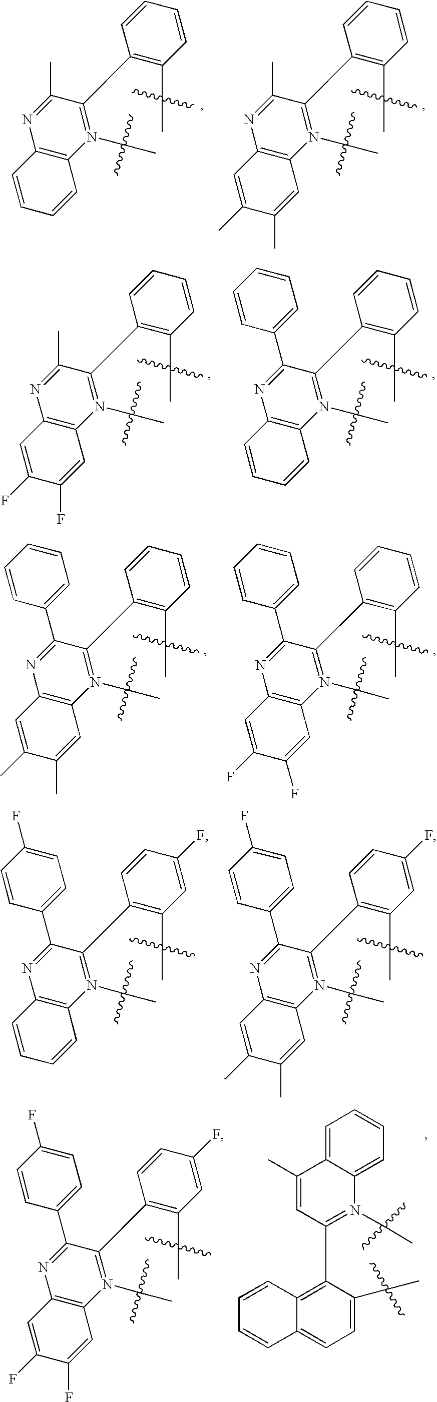

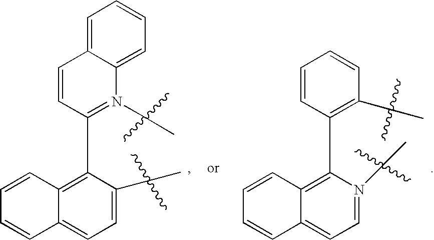

The N̂O bidentate ligand preferably is

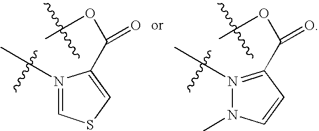

Representative examples of the phosphorescent organometallic complex guest materials include, but are not limited to:

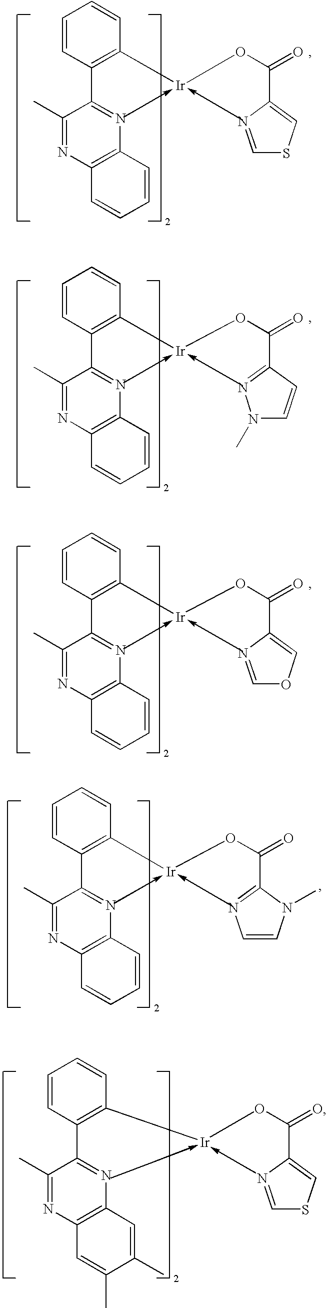

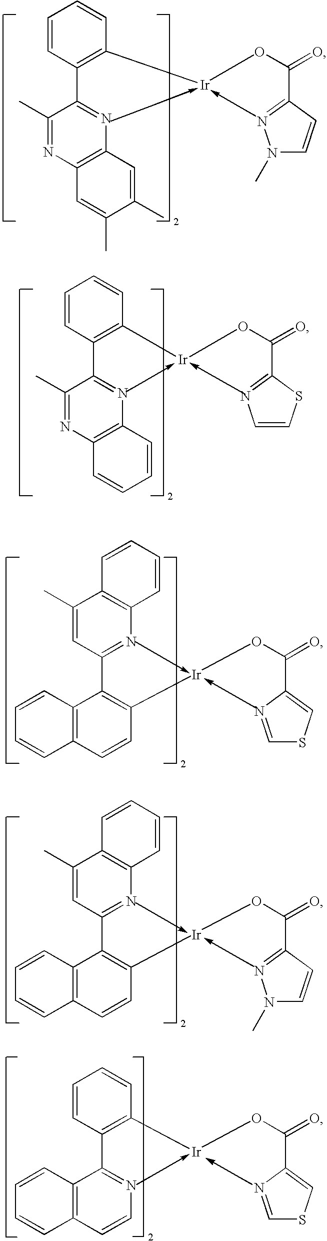

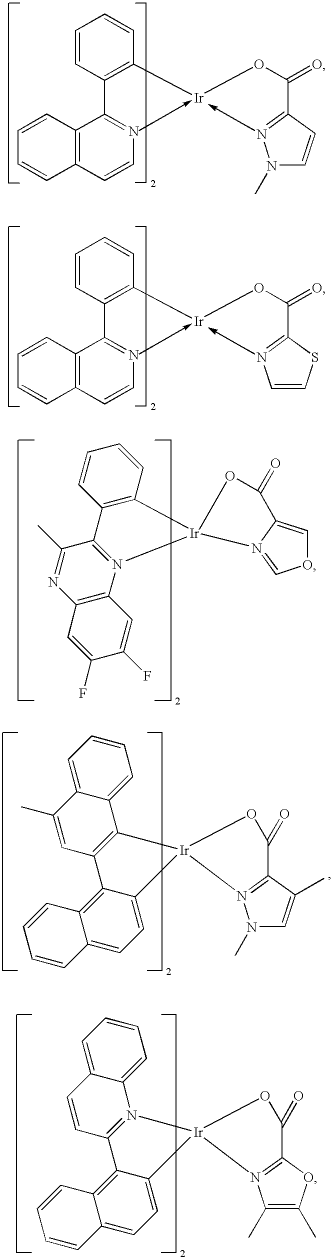

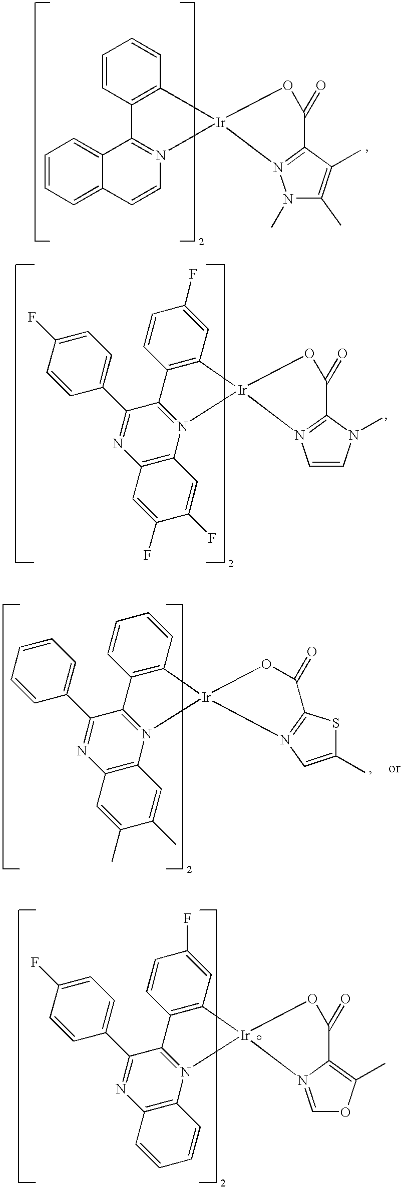

The organometallic complex of the invention is a light-emission material, and in some specific embodiments is a red phosphorescence-emission material. The red phosphorescent material may be used in a light-emission layer of an organic light-emitting diode (OLED). For example, the red phosphorescent material may be used as a dopant in the light-emission layer. The dopant and the doping quantity of the light-emission material can be varied according to the organic electro-luminescence material used and required device characteristics. Therefore, the present invention is not limited to the doping quantity of the dapant described herein.

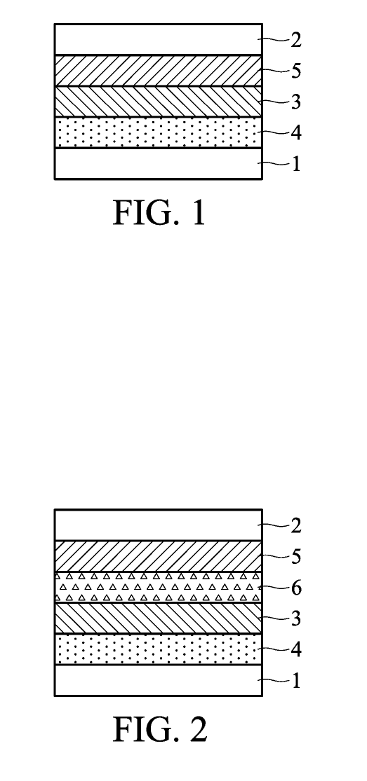

FIGS. 1-3 show organic light-emitting diodes, particularly red phosphorescent organic light-emitting diodes, according to embodiments of the present invention. The light-emission layer 3 including the organometallic complex of the invention is disposed between an anode 1 and a cathode 2. In embodiments, the metallic iridium complex is formed by the vacuum deposition method for forming the light-emission layer 3. Alternatively, the metallic iridium complex is doped (or co-doped) into a host material by the vacuum deposition method for forming the light-emission layer 3. Representative examples of the host material are, but not limited to, the following compounds:

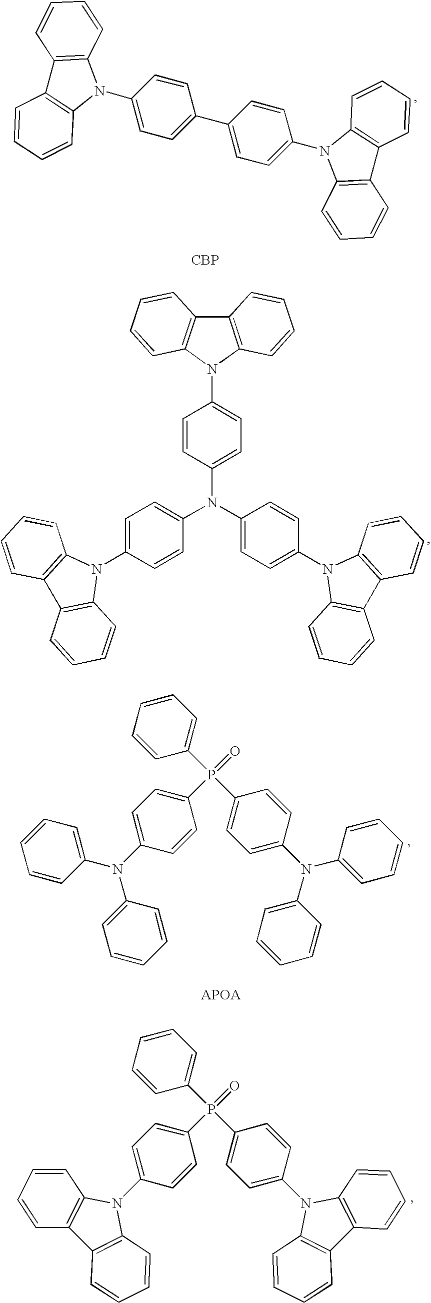

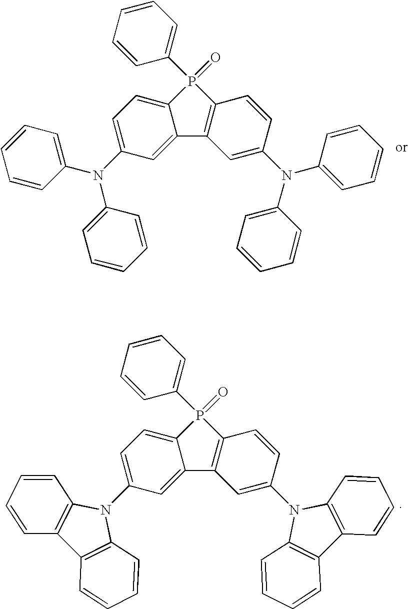

The anode 1 or cathode 2 includes, but is not limited to, indium tin oxide (ITO), indium zinc oxide (IZO), aluminum zinc oxide (AZO), zinc oxide (ZnO), SnO₂, In₂O₃, Al, Cu, Mo, Ti, Pt, Jr, Ni, Cr, Ag, Au, or combinations thereof. The anode 1 or cathode 2 may be formed by the method including, but is not limited to, sputtering, electron beam evaporation, thermal evaporation, or chemical vapor deposition.

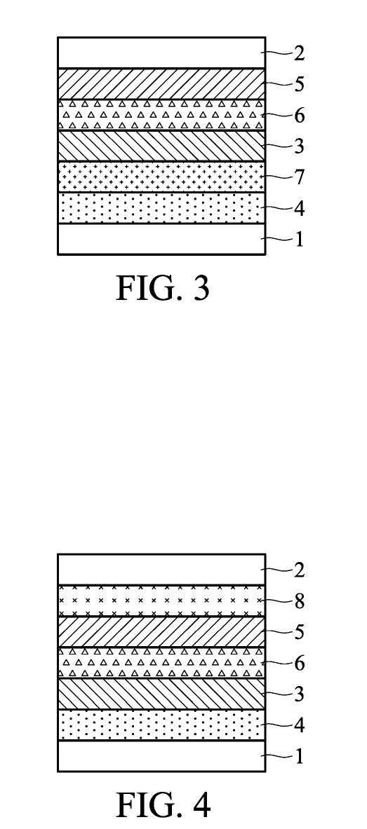

Between the anode 1 and the cathode 2 shown in FIG. 1, a hole-transport layer 4, a light-emission layer 3, and an electron-transport layer 5 are sequentially disposed on the anode 1. In FIG. 2, the hole-transport layer 4, the light-emission layer 3, a hole-blocker layer 6, and the electron-transport layer 5 are sequentially disposed on the anode 1. In FIG. 2, the hole-blocker layer 6 is inserted between the light-emission layer 3 and electron-transport layer 5, which is different from FIG. 1. In FIG. 3, the hole-transport layer 4, an electron-blocker layer 7, the light-emission layer 3, the hole-blocker layer 6, and the electron-transport layer 5 are sequentially disposed on the anode 1. In FIG. 3, the electron-blocker layer 7 is inserted between the hole transport layer 4 and the light emission layer 3, which is different from FIG. 2. In FIG. 4, the hole-transport layer 4, the light-emission layer 3, the hole-blocker layer 6, the electron-transport layer 5, and an electron-injection layer 8 are sequentially disposed on the anode 1. In FIG. 4, the electron-injection layer 8 is inserted between the cathode 2 and electron-transport layer 5, which is different from FIG. 1.

The hole-transport layer 4 includes, but is not limited to, N,N′-bis(naphthalene-1-yl)-N,N′-bis(phenyl)-benzidine (NPB), N,N,N′,N′-Tetrakis(naphth-2-yl)benzidine (TNB; NT2). The electron-transport layer 5 includes, but is not limited to, 4,7-diphenyl-1,10-phenathroline (BPhen), 2,9-dimethyl-4,7-diphenyl-1,10-phenathroline (BCP), 2,2′,2″-(1,3,5-benzinetriyl)-tris(1-phenyl-1-H-benzimidazole) (TBPI), tris(8-hydroxyquinoline)aluminum (Alq3). The hole-blocker layer 6 includes, but is not limited to, 4,7-diphenyl-1,10-phenathroline (BPhen), 2,9-dimethyl-4,7-diphenyl-1,10-phenanthroline (BCP), (III) bis(2-methyl-8-quinolinato)-4-phenyl-phenolato)aluminum(III) (BAlq), 1,3,5-tris(phenyl-2-benzimidazolyl)-benzene (TPBI), aluminium (III) bis(2-methyl-8-quninolinato)-phenolate (PAlq), aluminium (III) bis(2-methyl-8-quninolinato)-triphenylsilanyloxy (SAlq), or 1,4-bis(triphenylsilyl)benzene (UGH2). The electron-injection layer 8 includes, but is not limited to, an alkali metal halide, alkali earth metal halide, alkaline metal oxide, or metal carbonate, such as LiF, CsF, NaF, CaF₂, Li₂O, Cs₂O, Na₂O, Li₂CO₃, Cs₂CO₃ or Na₂CO₃.

Note that the formation methods the hole-transport layer 4, electron-transport layer 5, hole-blocker layer 6, electron-blocker layer 7, and electron-injection layer 8 are not limited, and can be conventional methods such as thermal vacuum evaporation, spin coating, immersion coating, rolling coating, ink refilling, embossing, impression, physical vapor deposition, or chemical vapor deposition. Moreover, the arrangement of the films of the invention is not limited to the structure shown in FIGS. 1-4. The arrangement of the films can be varied depending on desired device characteristics.

The following description is of the best-contemplated mode of carrying out the invention. This description is made for the purpose of illustrating the general principles of the invention and should not be taken in a limiting sense. The scope of the invention is best determined by reference to the appended claims.

### Example 1

### Synthesis of Compound (1)

The reaction according to Example 1 is shown as below:

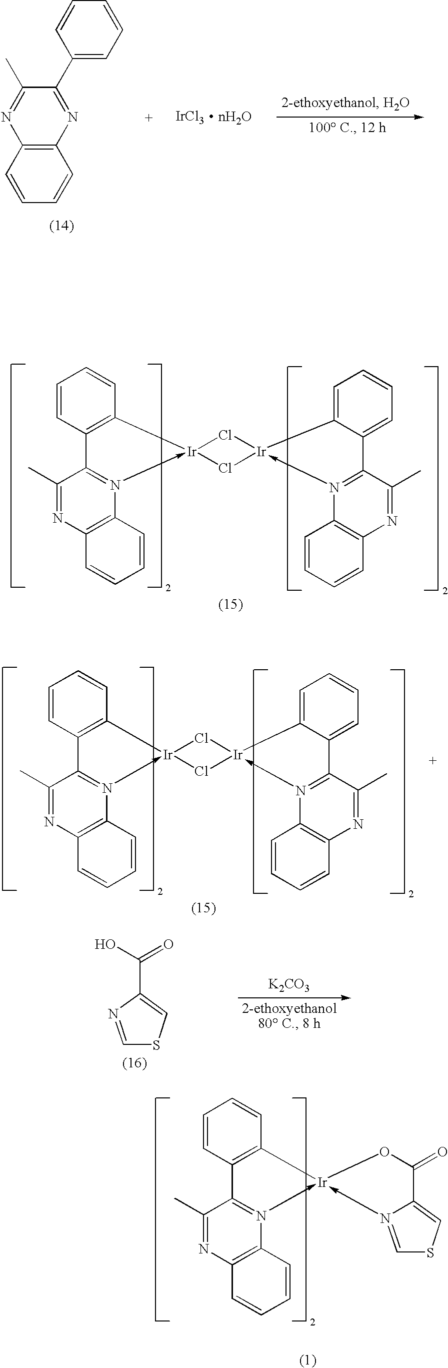

ĈN cyclometalated ligand (compound (14)) (2.2 mmol), IrCl₃.nH₂O (0.375 g, 1.0 mmol) and a solvent of ethoxy-ethanol and water (3:1) (4.0 ml) were put into a flask. The solution was heated to 100˜120° C. over 12 hours, and then filtered to obtain a solid. After the solid was washed with n-Hexane and water, it was dried, thus obtaining a red or purple solid, which was an Ir complex dimmer (compound (15)) having chlorine bridges, yield of about 75˜90%.

The Ir complex dimmer (compound (15)) (1 mmol)), Potassium carbonate (0.304 g, 2.2 mmol), and ancillary ligand (compound (16)) (2.2 mmol) was put into a flask, and then mixed well. A solvent of 2-ethoxyethanol (2.0 ml) was then put into the flask. The solution was heated to 80° C. for 12 hours, and then filtered to obtain a solid. After the solid was washed with ethyl ether and water, it was dried, thus obtaining a red solid, yield of about 73%.

Spectrum Data of Compound (1)

¹H NMR (400 MHz, CD₂Cl₂, ppm): δ 8.53 (d, J=8.8 Hz, 1H), 8.42 (d, J=8.4 Hz, 1H), 8.27 (d, J=8.4 Hz, 1H), 8.23 (d, J=2.4 Hz, 1H), 7.99 (d, J=8.0 Hz, 1H), 7.94 (d, J=8 Hz, 1H), 7.64 (m, 1H), 7.59 (d, J=2.4 Hz, 1H), 7.53 (m, 2H), 7.39 (d, J=8.8 Hz, 1H), 7.17 (m, 1H), 7.08 (m, 2H), 6.88 (d, J=8.0 Hz, 1H), 6.80 (m, 1H), 6.68 (m, 1H), 6.28 (d, J=8 Hz, 1H), 3.36 (s, 3H), 3.35 (s, 3H).

High-resolution mass spectrometry (HRMS) (m/z): Calcd. for C₃₄H₂₄IrN₅O₂S, 759.1280, found 759.1268.

### Example 2

### Synthesis of Compound (2)

The reaction according to Example 2 is shown as below:

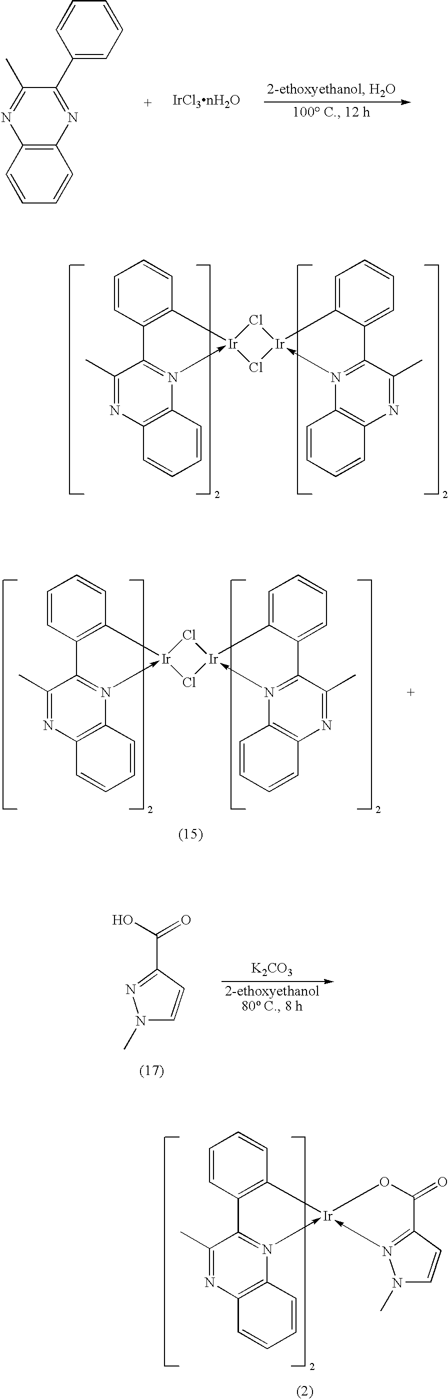

The fabrication steps of this example were similar to that described in Example 1, wherein the compound (15) reacted with compound (17) (which was used as the ancillary ligand). A red solid product, yield of 70%, was obtained.

Spectrum Data of Compound (2)

¹H NMR (400 MHz, CD₂Cl₂, ppm): δ 8.84 (d, J=8.8 Hz, 1H), 8.35 (d, J=8.4 Hz, 1H), 8.23 (d, J=8.4 Hz, 1H), 8.00 (m, 2H), 7.66 (m, 1H), 7.56 (m, 2H), 7.32 (d, J=8.4 Hz, 1H), 7.13 (m, 3H), 7.05 (m, 1H), 6.87 (d, J=8.4 Hz, 1H), 6.78 (t, J=7.2 Hz, 1H), 6.67 (t, J=7.2 Hz, 1H), 6.22 (d, J=2.4 Hz, 1H), 6.16 (d, J=8 Hz, 1H), 3.34 (s, 3H), 3.33 (s, 3H), 3.27 (s, 3H).

High-resolution mass spectrometry (HRMS) (m/z): Calcd. for C₃₅H₂₇IrN₆O₂, 756.1825, found 756.1830.

### Example 3

### Synthesis of Compound (3)

The reaction according to Example 3 is shown as below:

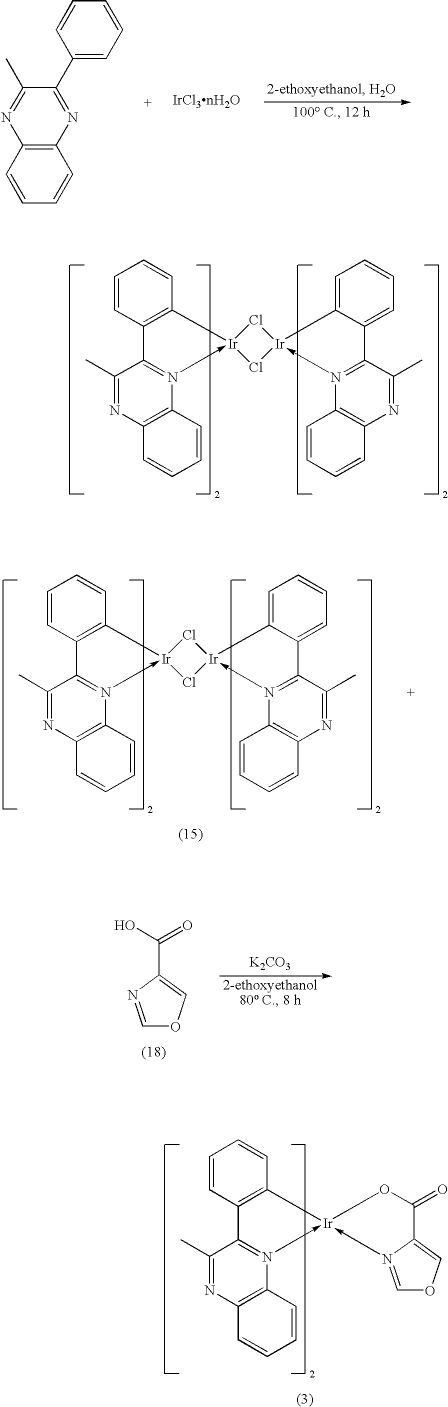

The fabrication steps of this example were similar to that described in Example 1, wherein the compound (15) reacted with compound (18) (which was used as the ancillary ligand). A red solid product, yield of 67%, was obtained.

Spectrum Data of Compound (3)

¹H NMR (400 MHz, CDCl₃, ppm): δ 8.49 (d, J=9.2 Hz, 1H), 8.30 (d, J=8.4 Hz, 1H), 8.18 (d, J=8.4 Hz, 1H), 8.00 (d, J=8.0 Hz, 1H), 7.94 (d, J=8.0 Hz, 1H), 7.66 (d, J=0.8 Hz, 1H), 7.64 (d, J=0.8 Hz, 1H), 7.61 (m, 2H), 7.53 (m, 2H), 7.11 (m, 2H), 7.00 (t, J=7.6 Hz, 1H), 6.88 (d, J=8.0 Hz, 1H), 6.78 (t, J=7.6 Hz, 1H), 6.64 (t, J=7.6 Hz, 1H), 6.24 (d, J=6.8 Hz, 1H) 3.33 (s, 3H), 3.32 (s, 3H)

High-resolution mass spectrometry (HRMS) (m/z): Calcd. for C₃₄H₂₄IrN₅O₃, 743.1508, found 743.1513.

### Example 4

### Synthesis of Compound (4)

The reaction according to Example 4 is shown as below:

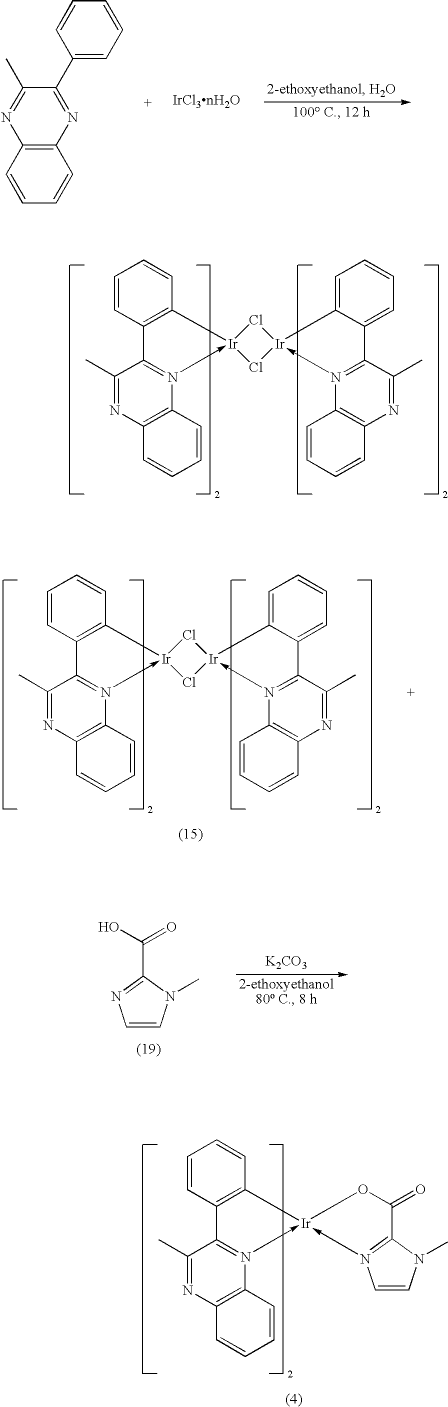

The fabrication steps of this example were similar to that described in Example 1, wherein the compound (15) reacted with compound (19) (which was used as the ancillary ligand). A red solid product, yield of 51%, was obtained.

Spectrum Data of Compound (4)

¹H NMR (400 MHz, CDCl₃, ppm): δ 8.49 (d, J=8.8 Hz, 1H), 8.30 (d, J=8.0 Hz, 1H), 8.21 (d, J=8.0 Hz, 1H), 7.96 (m, 2H), 7.62 (t, J=7.6 Hz, 1H), 7.52 (m, 3H), 7.11 (m, 2H), 7.01 (d, J=7.6 Hz, 1H), 6.80 (d, J=8.0 Hz, 1H), 6.74 (m, J=7.6, 2H), 6.64 (s, 1H), 6.48 (s, 1H), 6.33 (d, J=7.6 Hz, 1H), 3.68 (s, 3H), 3.34 (s, 3H), 3.33 (s, 3H).

### Example 5

### Synthesis of Compound (5)

The reaction according to Example 5 is shown as below:

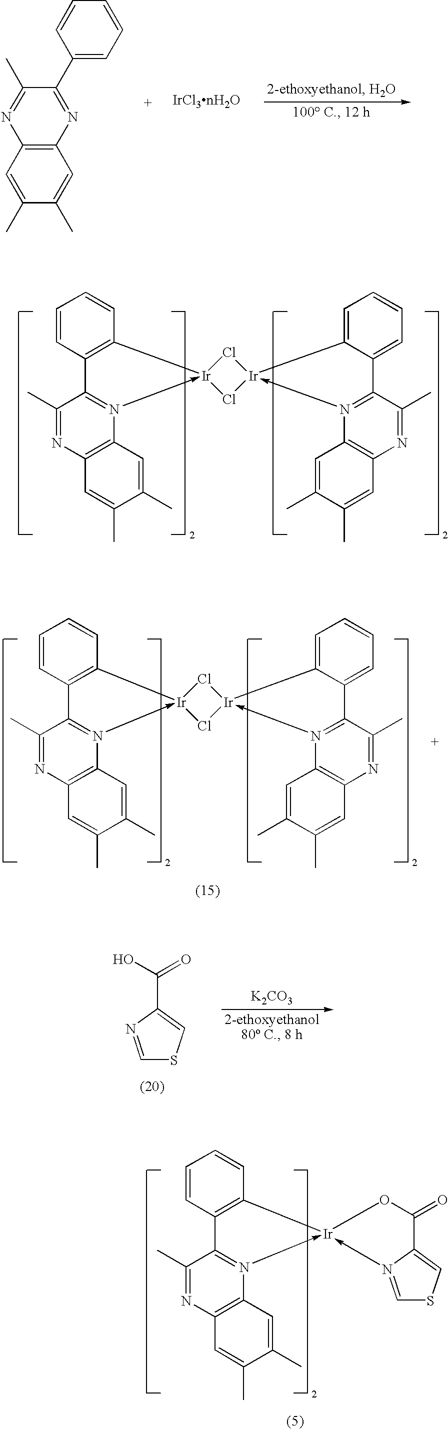

The fabrication steps of this example were similar to that described in Example 1, wherein the compound (15) reacted with compound (20) (which was used as the ancillary ligand). A red solid product, yield of 68%, was obtained.

Spectrum Data of Compound (5)

¹H NMR (400 MHz, CD₂Cl₂, ppm): δ 8.40 (s, 1H), 8.33 (d, J=8 Hz, 1H), 8.21 (m, 2H), 7.73 (s, 1H), 7.68 (s, 1H), 7.64 (d, J=2 Hz, 1H), 7.19 (s, 1H), 7.12 (t, J=7.2 Hz, 1H), 7.02 (t, J=7.2 Hz, 1H), 6.83 (d, J=7.6 Hz, 1H), 6.75 (t, J=7.6 Hz, 1H), 6.63 (t, J=7.6 Hz, 1H), 6.23 (d, J=7.6 Hz, 1H), 3.33 (s, 3H), 3.32 (s, 3H), 2.43 (s, 3H), 2.38 (s, 3H), 2.32 (s, 3H), 1.96 (s, 3H).

High-resolution mass spectrometry (HRMS) (m/z): Calcd. for C₃₈H₃₂IrN₅O₂S, 815.1906, found 815.1915.

### Example 6

### Synthesis of Compound (6)

The reaction according to Example 6 is shown as below:

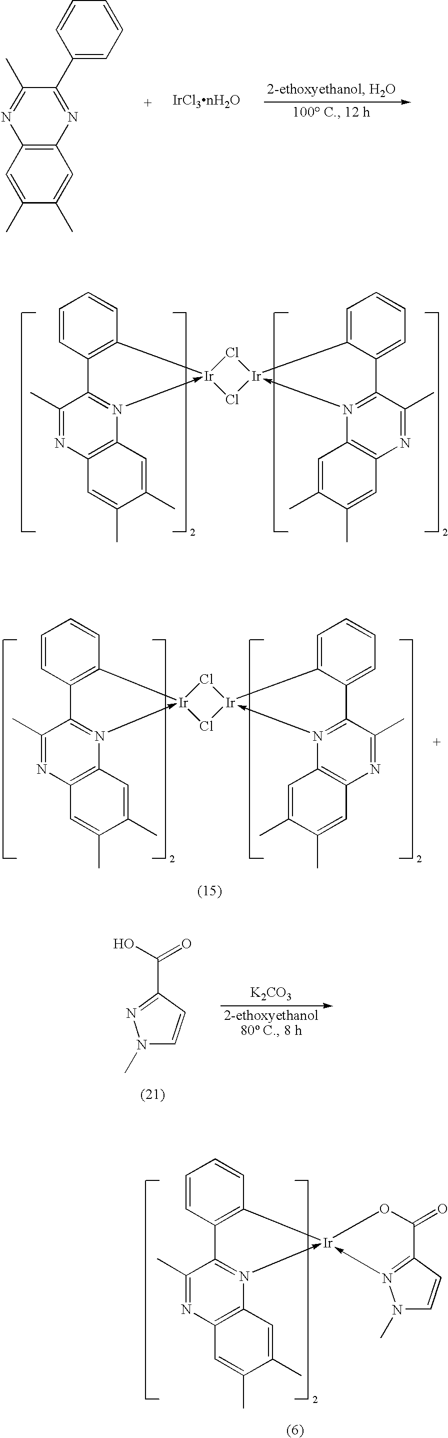

The fabrication steps of this example were similar to that described in Example 1, wherein the compound (15) reacted with compound (21) (which was used as the ancillary ligand). A red solid product, yield of 70%, was obtained.

Spectrum Data of Compound (6)

¹H NMR (400 MHz, CD₂Cl₂, ppm): δ 8.73 (s, 1H), 8.31 (d, J=8.0 Hz, 1H), 8.18 (d, J=8.0 Hz, 1H), 7.76 (s, 1H), 7.74 (s, 1H), 7.15 (d, J=2.4 Hz, 1H), 7.03 (m, 3H), 6.83 (d, J=8.0 Hz, 1H), 6.73 (t, J=7.6 Hz, 1H), 6.64 (t, J=7.6 Hz, 1H), 6.30 (d, J=2.4 Hz, 1H), 6.12 (d, J=8.0 Hz, 1H), 3.30 (s, 3H), 3.28 (s, 3H) 3.24 (s, 3H) 2.43 (s, 3H) 2.39 (s, 3H), 2.32 (s, 3H).

### Example 7

### Synthesis of Compound (7)

The reaction according to Example 7 is shown as below:

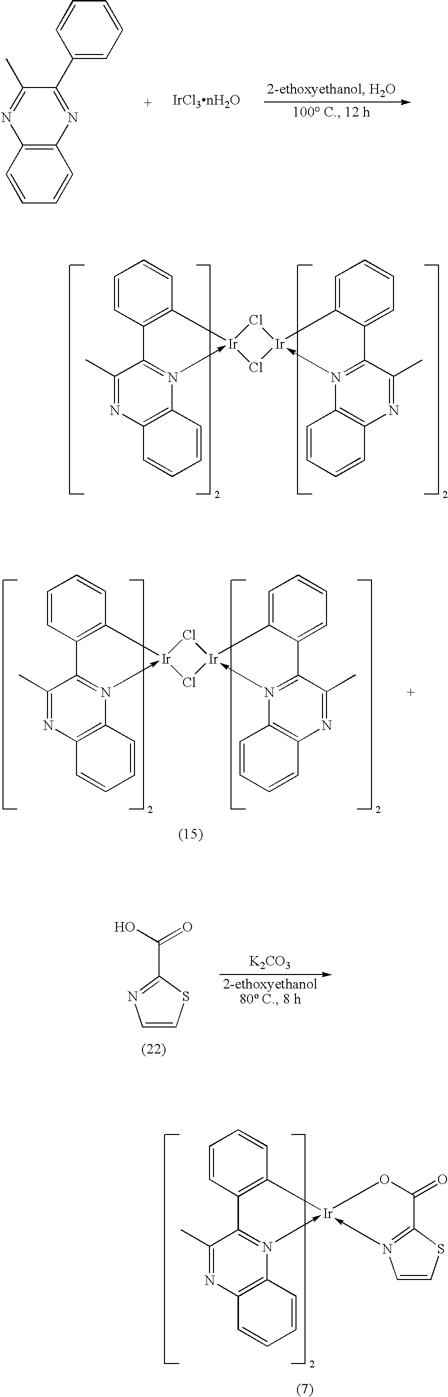

The fabrication steps of this example were similar to that described in Example 1, wherein the compound (15) reacted with compound (22) (which was used as the ancillary ligand). A red solid product, yield of 48%, was obtained.

Spectrum Data of Compound (7)

¹H NMR (400 MHz, CDCl₃, ppm): δ 8.49 (d, J=8.4 Hz, 1H), 8.34 (d, J=8.0 Hz, 1H), 8.21 (d, J=8.0 Hz, 1H), 7.99 (d, J=8.4 Hz, 1H), 7.94 (d, J=8.4 Hz, 1H), 7.63 (t, J=8.4 Hz, 1H), 7.52 (m, 2H), 7.35 (d, J=3.2 Hz, 1H), 7.28 (m, 2H), 7.15 (t, J=7.6, 1H), 7.02 (m, 2H), 6.87 (d, J=7.6 Hz, 1H), 6.79 (t, J=6.8 Hz, 1H), 6.67 (t, J=6.8 Hz, 1H), 6.29 (d, J=7.6 Hz, 1H) 3.35 (s, 3H), 3.34 (s, 3H).

### Example 8

### Synthesis of Compound (8)

The reaction according to Example 8 is shown as below:

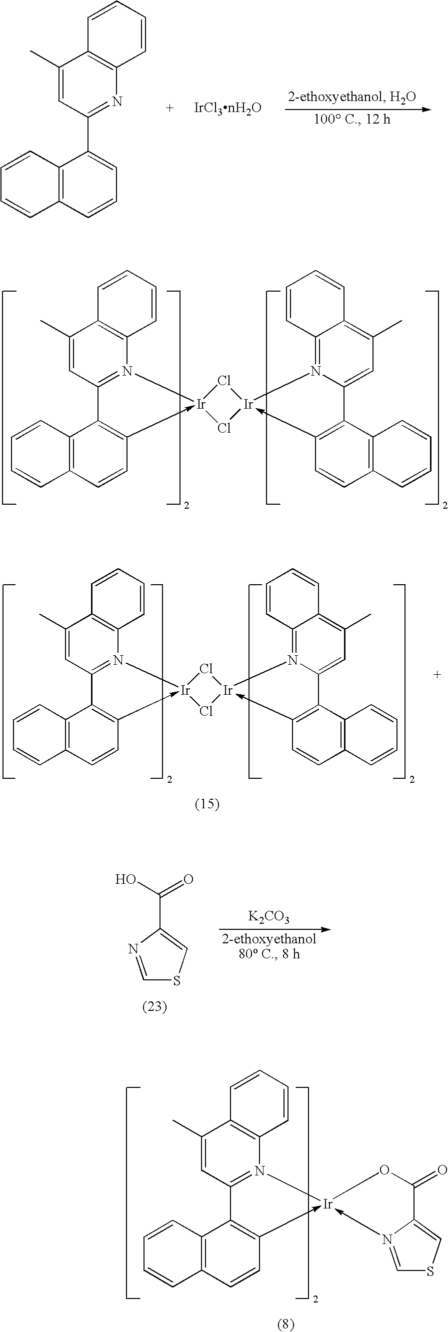

The fabrication steps of this example were similar to that described in Example 1, wherein the compound (15) reacted with compound (23) (which was used as the ancillary ligand). A red solid product, yield of 55%, was obtained.

Spectrum Data of Compound (8)

¹H NMR (400 MHz, CD₂Cl₂, ppm): δ 8.81 (d, J=8.4 Hz, 1H), 8.70 (m, 2H), 8.63 (s, 1H), 8.56 (s, 1H), 8.21 (d, J=2.4 Hz, 1H), 7.96 (m, 2H), 7.78 (d, J=6.8, 1H), 7.66 (m, 2H), 7.54 (m, 4H), 7.43 (t, J=7.2, 1H), 7.35 (m, 3H), 7.14 (d, J=1.6 Hz, 2H), 7.03 (d, J=8.4 Hz, 1H), 6.95 (t, J=6.8 Hz, 1H), 6.37 (d, J=8.4 Hz, 1H), 2.99 (s, 3H), 2.96 (s, 3H).

High-resolution mass spectrometry (HRMS) (m/z): Calcd. for C₄₄H₃₀IrN₃O₂S, 857.1688, found 857.1682.

### Example 9

### Synthesis of Compound (9)

The reaction according to Example 9 is shown as below:

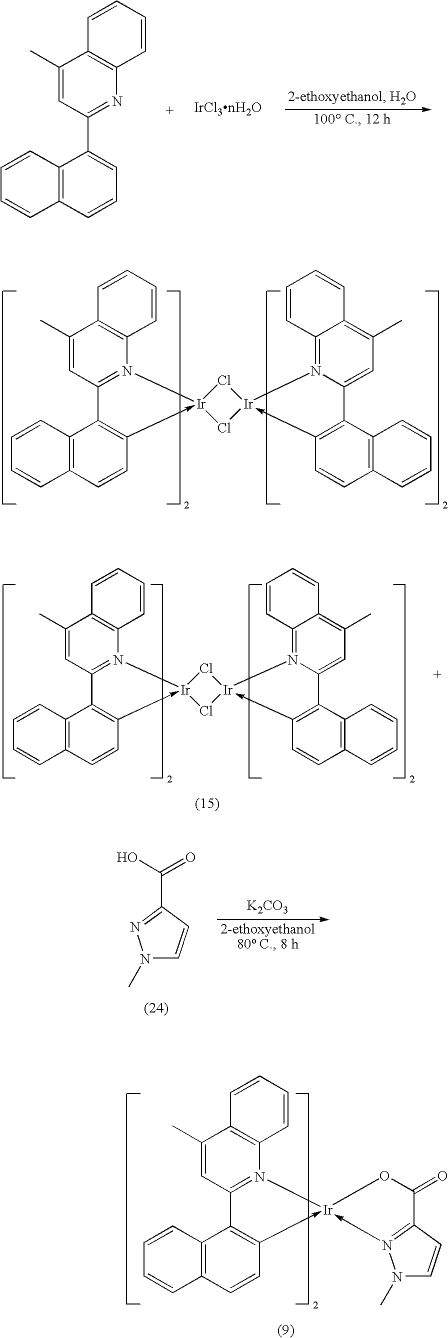

The fabrication steps of this example were similar to that described in Example 1, wherein the compound (15) reacted with compound (24) (which was used as the ancillary ligand). A red solid product, yield of 58%, was obtained.

Spectrum Data of Compound (9)

¹H NMR (400 MHz, CDCl₃, ppm): δ 8.91 (m, 1H), 8.72 (d, J=8.4 Hz, 1H), 8.67 (d, J=8.4 Hz, 1H), 8.57 (s, 1H), 8.53 (s, 1H), 8.03 (d, J=7.2 Hz, 1H), 7.98 (m, 1H), 7.70 (d, J=7.6 Hz, 1H), 7.65 (d, J=7.6 Hz, 1H), 7.56 (m, 4H), 7.43 (m, 2H), 7.35 (m, 2H), 7.14 (m, 5H), 6.54 (d, J=8.4 Hz, 1H), 6.18 (d, J=2.8 Hz, 1H), 3.19 (s, 3H), 3.02 (s, 3H), 2.99 (s, 3H).

High-resolution mass spectrometry (HRMS) (m/z): Calcd. for C₄₅H₃₃IrN₄O₂, 854.2233, found 854.2237.

### Example 10

### Synthesis of Compound (10)

The reaction according to Example 10 is shown as below:

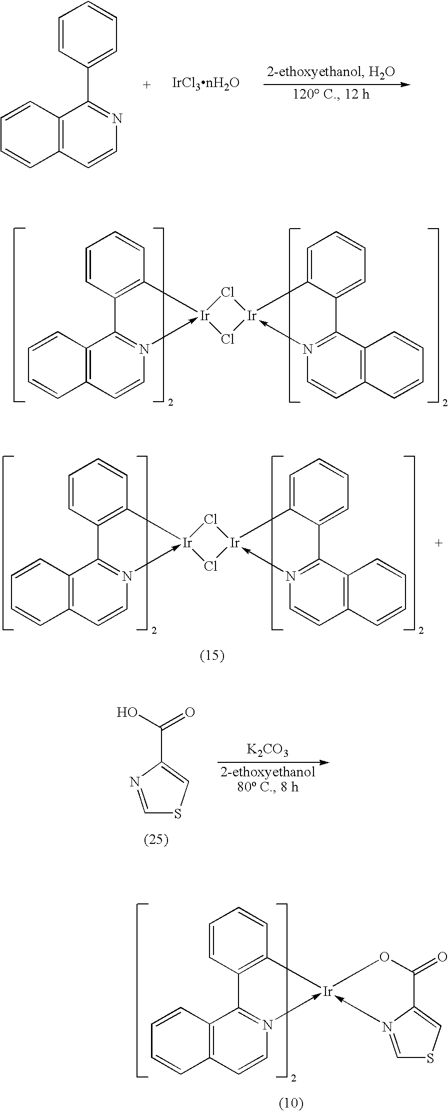

The fabrication steps of this example were similar to that described in Example 1, wherein the compound (15) reacted with compound (25) (which was used as the ancillary ligand). A red solid product, yield of 78%, was obtained.

Spectrum Data of Compound (10)

¹H NMR (400 MHz, CD₂Cl₂, ppm): δ 8.99 (m, 2H), 8.73 (d, J=6.4 Hz, 1H), 8.28 (d, J=8.4 Hz, 1H), 8.24 (d, J=8.4 Hz, 1H), 8.12 (d, J=2 Hz, 1H), 7.96 (m, 3H), 7.77 (m, 4H), 7.55 (d, J=6.4 Hz, 1H), 7.53 (d, J=6.4 Hz, 1H), 7.40 (s, J=6.0 Hz, 1H), 7.00 (m, 2H), 6.75 (m, 2H), 6.51 (d, J=7.6 Hz, 1H), 6.22 (d, J=7.6 Hz, 1H).

High-resolution mass spectrometry (HRMS) (m/z): Calcd. for C₃₄H₂₂IrN₃O₂S, 729.1062, found 729.1078.

### Example 11

### Synthesis of Compound (11)

The reaction according to Example 11 is shown as below:

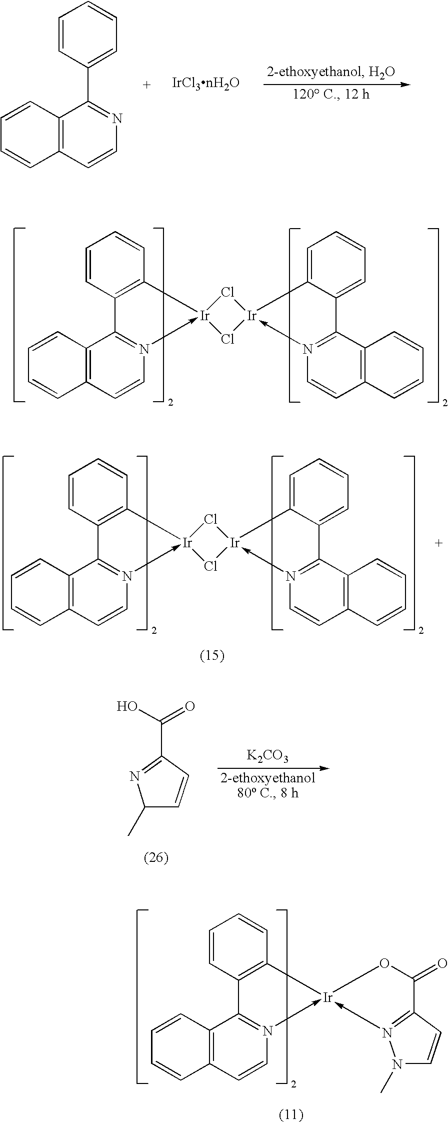

The fabrication steps of this example were similar to that described in Example 1, wherein the compound (15) reacted with compound (26) (which was used as the ancillary ligand). A red solid product, yield of 80%, was obtained.

Spectrum data of compound (11)

¹H NMR (400 MHz, CD₂Cl₂, ppm): δ 8.98 (m, 2H), 8.73 (d, J=6.4 Hz, 1H), 8.28 (d, J=7.6 Hz, 1H), 8.22 (d, J=7.6 Hz, 1H), 7.95 (m, 2H), 7.77 (m, 4H), 7.58 (m, 2H), 7.42 (d, J=6.4 Hz, 1H), 7.31 (d, J=2.8 Hz, 1H), 7.00 (m, 2H), 6.72 (m, 3H), 6.45 (d, J=7.6 Hz, 1H), 6.13 (d, J=7.6 Hz, 1H), 3.04 (s, 3H).

### Example 12

### Synthesis of Compound (12)

The reaction according to Example 12 is shown as below:

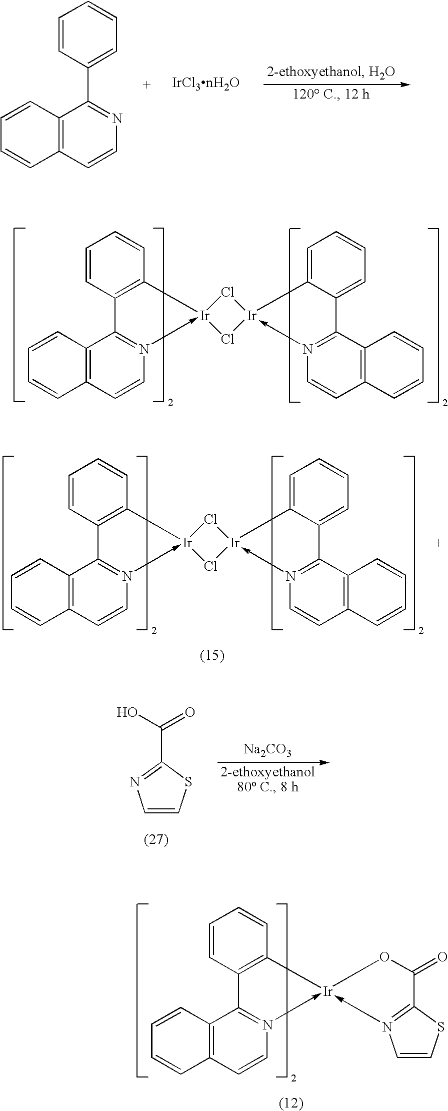

The fabrication steps of this example were similar to that described in Example 1, wherein the compound (15) reacted with compound (27) (which was used as the ancillary ligand). A red solid product, yield of 65%, was obtained.

Spectrum Data of Compound (12)

¹H NMR (400 MHz, CD₂Cl₂, ppm): δ 8.99 (m, 2H), 8.68 (d, J=6.4 Hz, 1H), 8.26 (m, 2H), 7.97 (m, 2H), 7.77 (m, 4H), 7.58 (d, J=6.0 Hz, 1H), 7.50 (m, 2H), 7.41 (d, J=6.4 Hz, 1H), 7.00 (m, 3H), 6.76 (m, 2H), 6.50 (d, J=8.0 Hz, 1H), 6.21 (d, J=8.0 Hz, 1H).

### Example 13

### Synthesis of Compound (13)

The reaction according to Example 13 is shown as below:

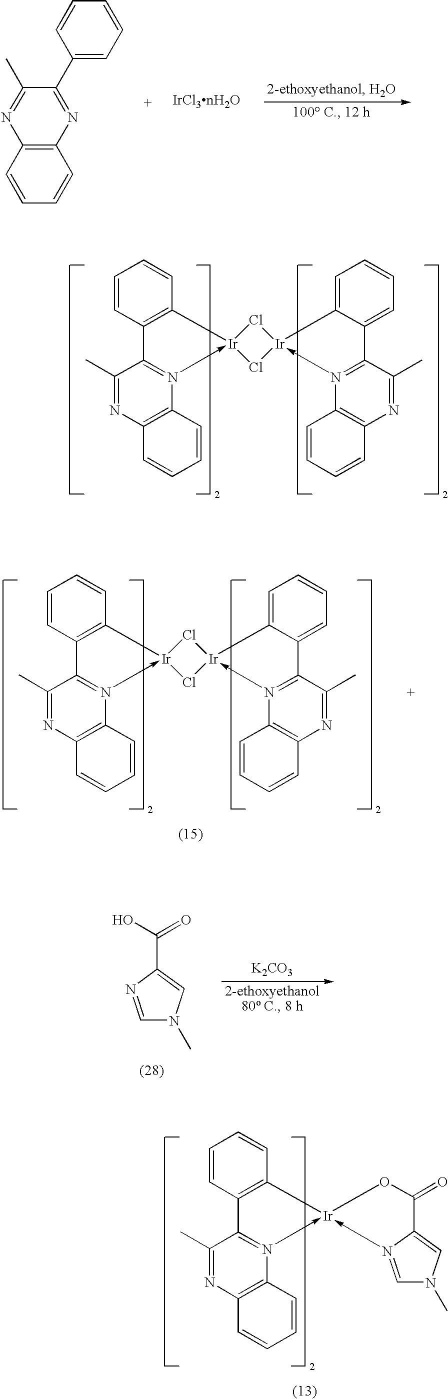

The fabrication steps of this example were similar to that described in Example 1, wherein the compound (15) reacted with compound (28) (which was used as the ancillary ligand). A red solid product, yield of 67%, was obtained.

Spectrum Data of Compound (13)

¹H NMR (400 MHz, CDCl₃, ppm): δ 8.46 (d, J=8.8 Hz, 1H), 8.28 (d, J=8.0 Hz, 1H), 8.20 (d, J=8.0 Hz, 1H), 7.94 (m, 2H), 7.60 (t, J=7.2 Hz, 1H), 7.49 (m, 3H), 7.06 (m, 2H), 6.99 (t, J=7.6 Hz, 1H), 6.78 (d, J=7.2 Hz, 1H), 6.71 (t, J=7.6 Hz, 1H), 6.64 (m, 2H), 6.46 (s, 1H), 6.31 (d, J=7.6 Hz, 1H), 3.66 (s, 1H), 3.32 (s, 1H), 3.30 (s, 1H).

### Analysis

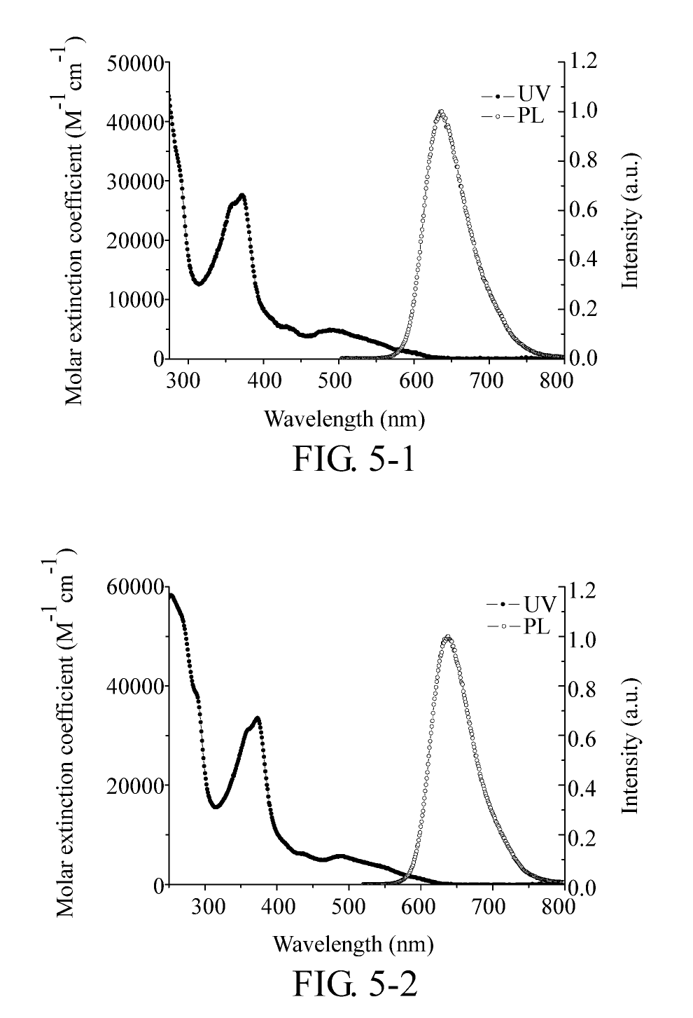

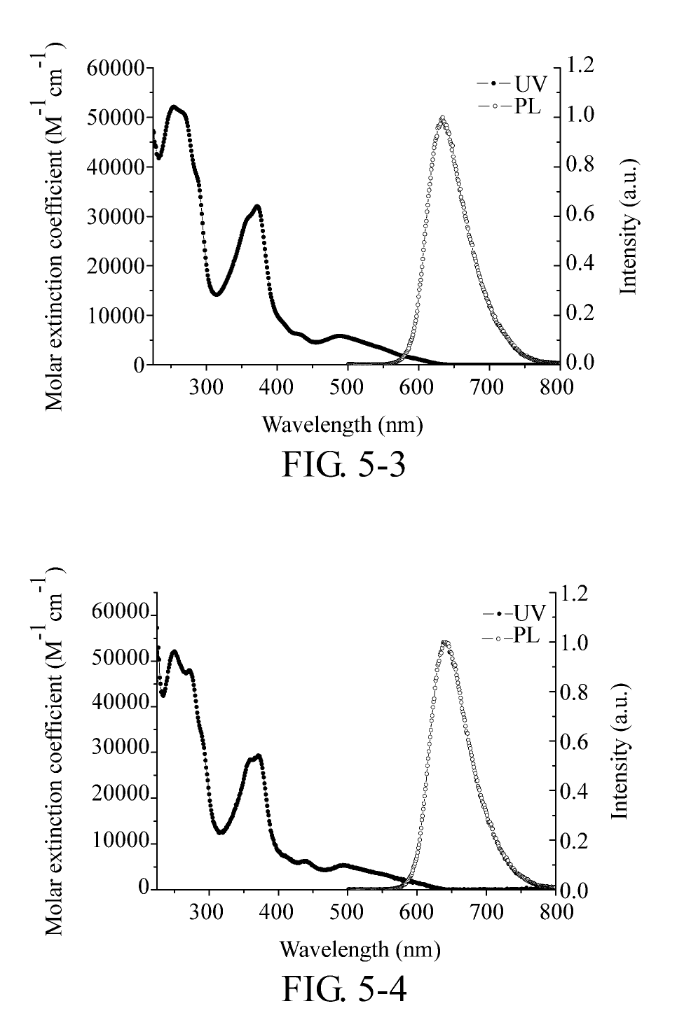

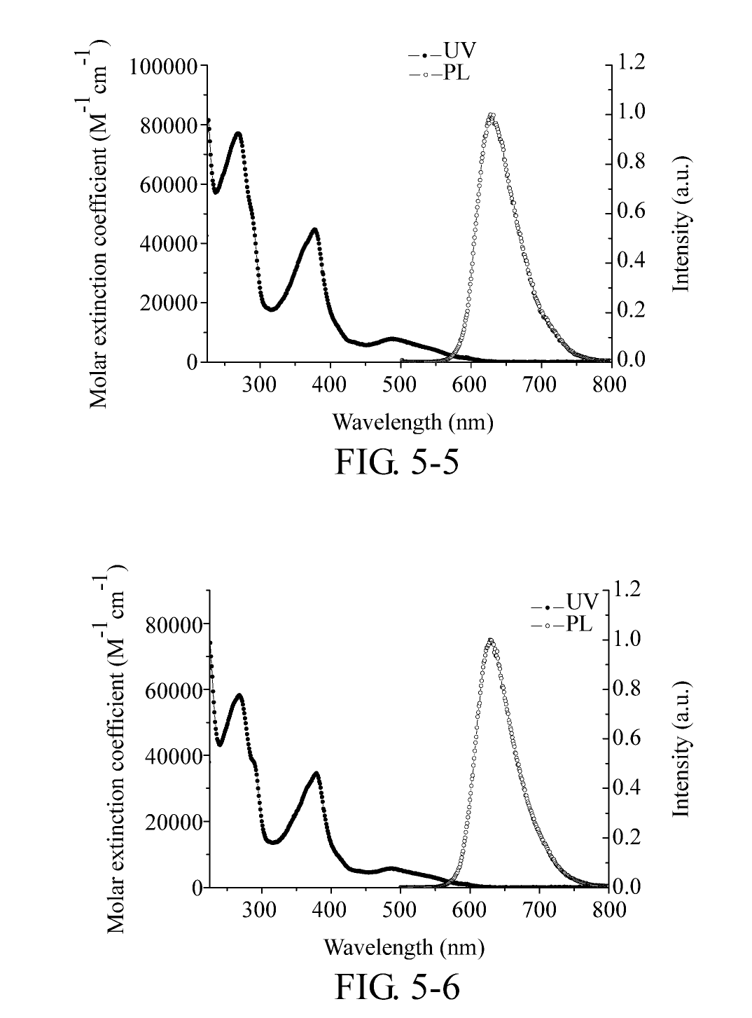

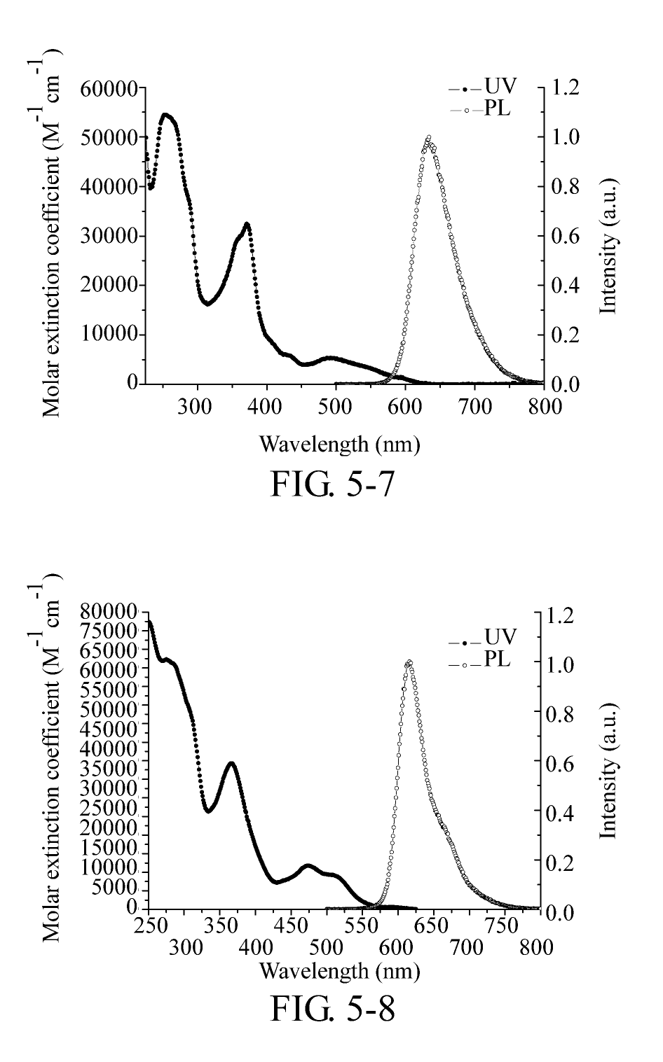

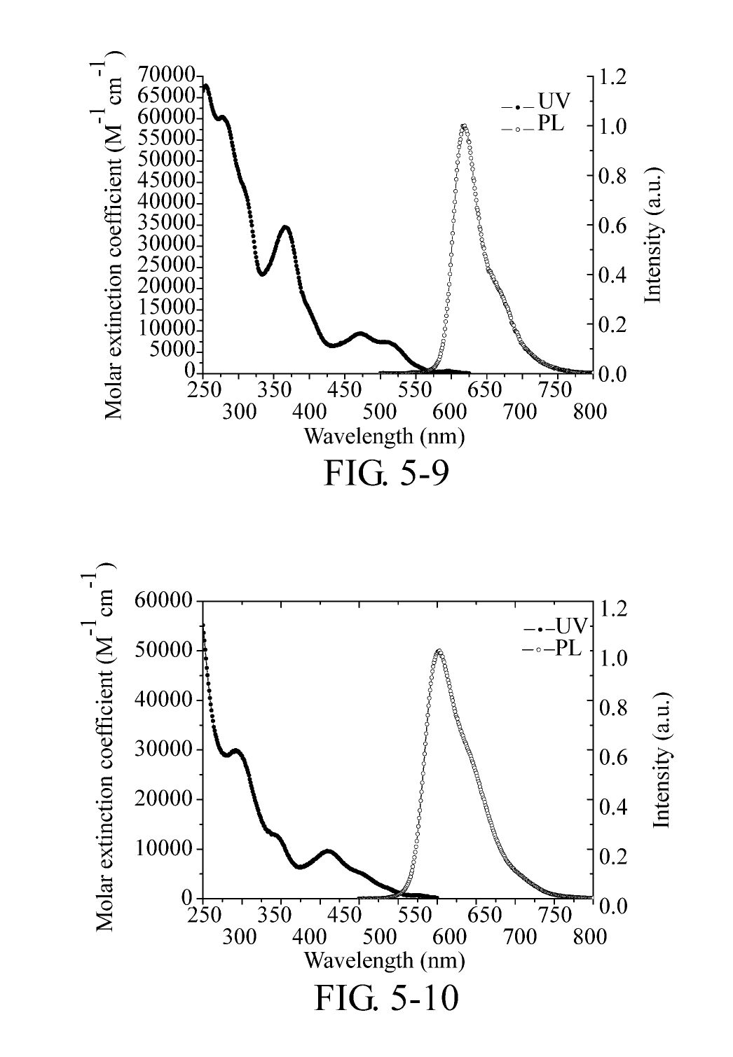

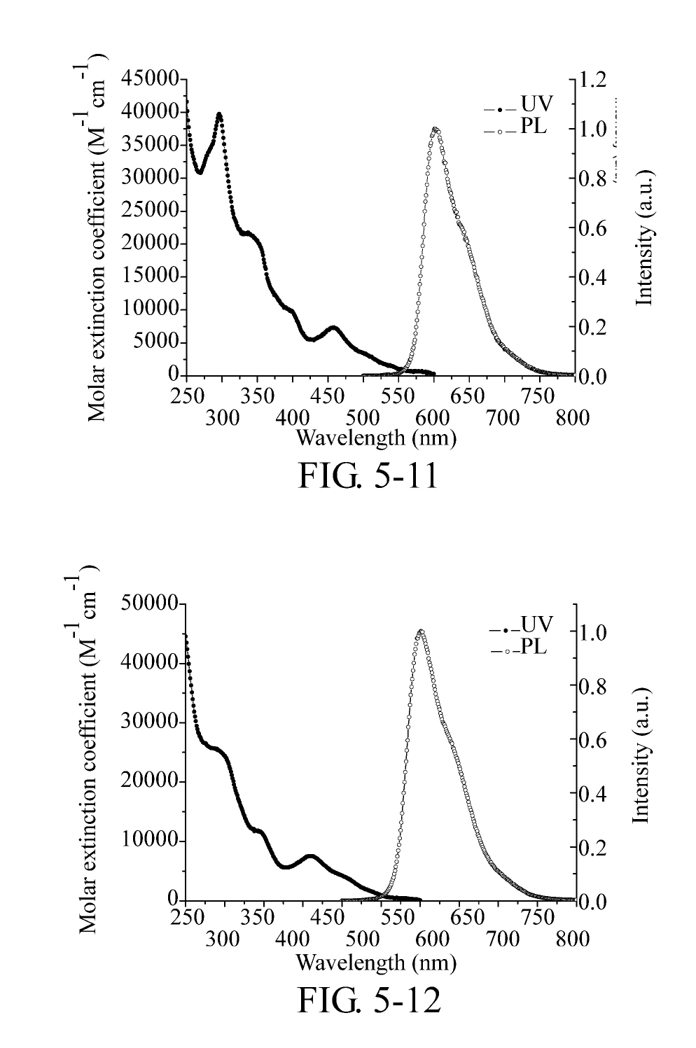

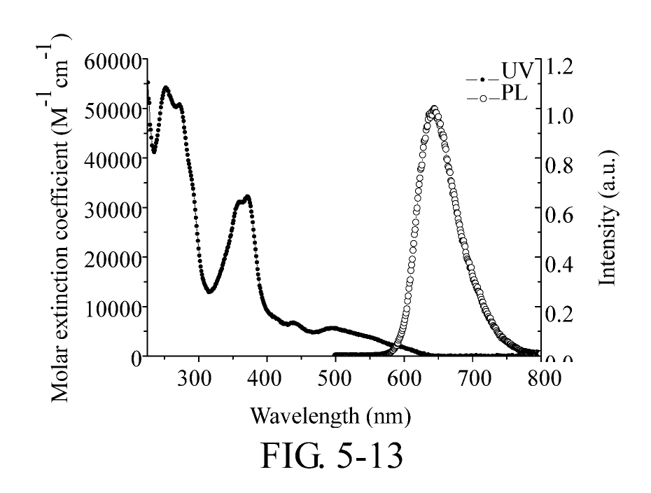

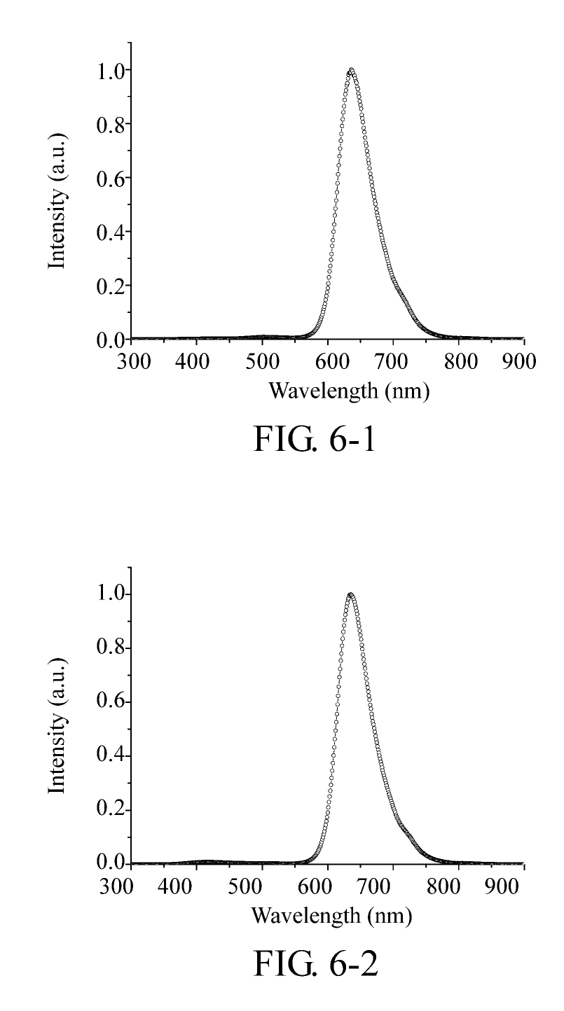

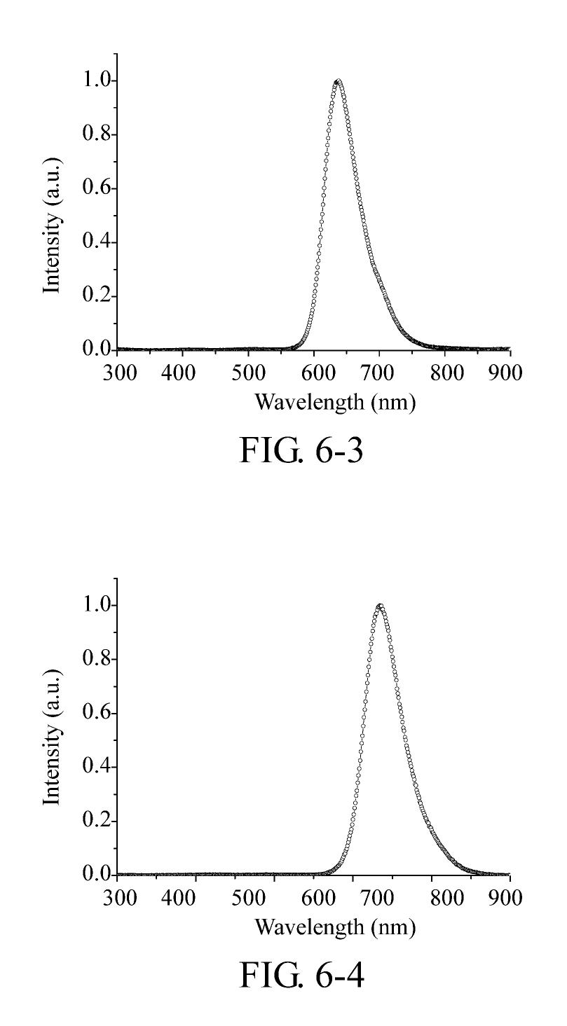

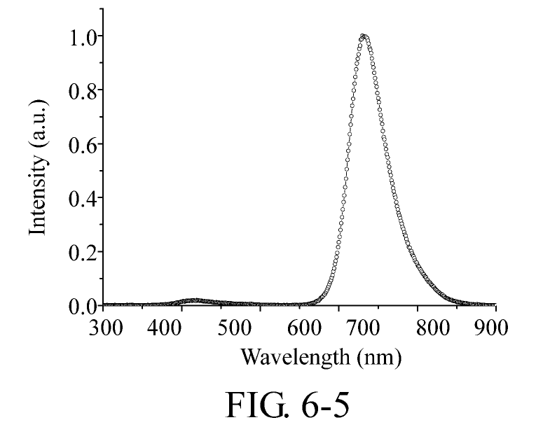

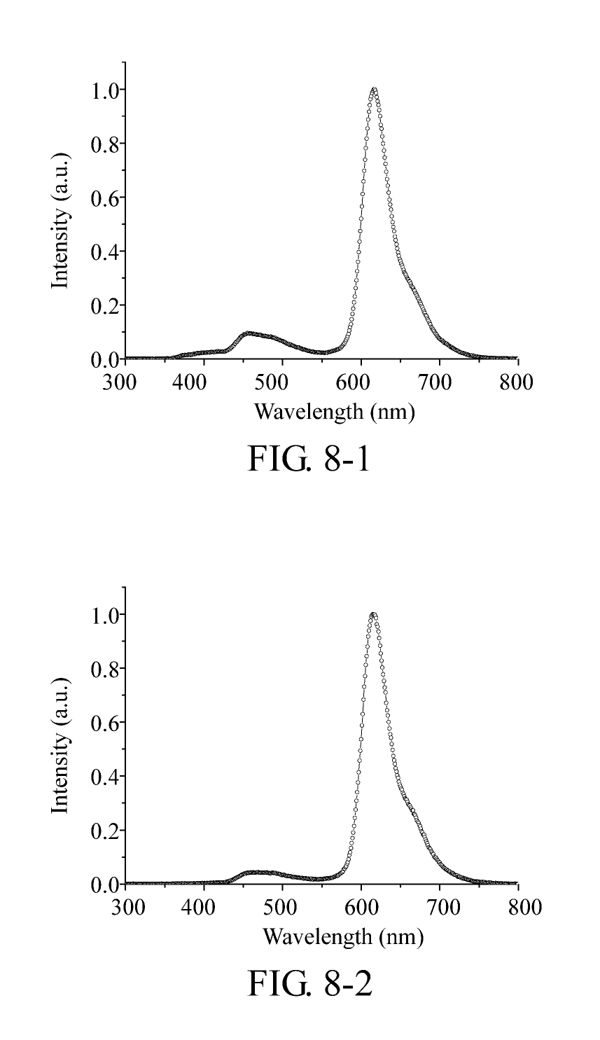

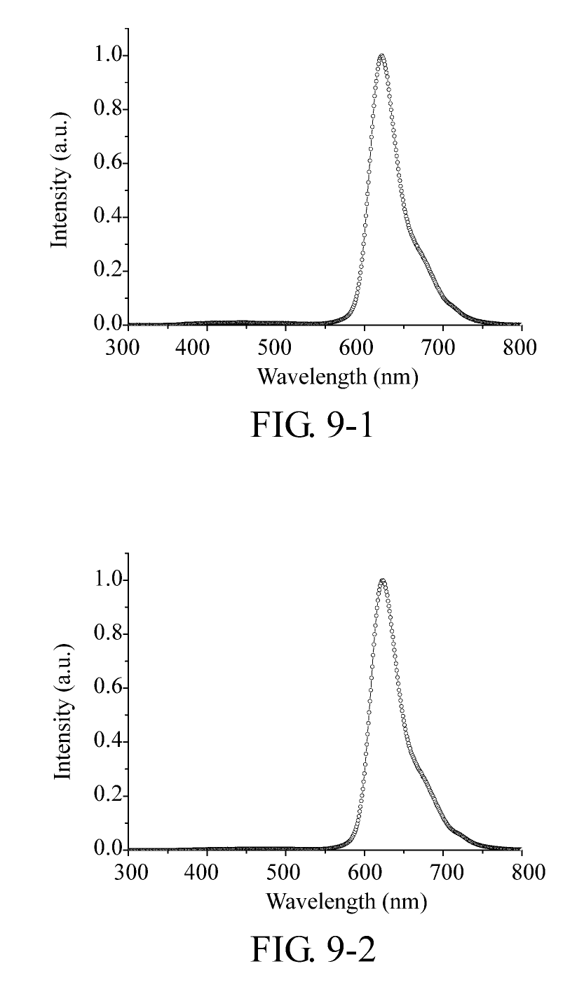

The products (compound (1) to compound (13)) obtained from Example 1 to Example 13 were tested. FIGS. 5-1 to 5-13 respectively show spectrograms of the UV-vis absorption and photoluminescence (PL) (dissolved in dichloromethane (DCM), 10⁻⁵M) of the compounds (1) to (13). The optical properties of the compounds (1) to (13) are shown in Table 1. In Table 1, λ_{abs} represents the UV-vis absorption wave length and λₑₘ represents the PL emission wavelength. The HOMO energy was obtained by cyclic voltammetry with ferrocene as a reference, as given by equation: 4.8 (ferrocene)+Eox obtained from the compound. ΔE is the band gap determined by the UV-vis onset absorption. The LUMO energy was obtained by the equation: the HOMO energy−ΔE.

TABLE 1
Optical properties of compounds (1) to (13)

| | λ_{abs} | λₑₘ | HOMO | LUMO | ΔE |
|---|---|---|---|---|---|
| Compound | [nm] | [nm] | [eV] | [eV] | [eV] |
| compound (1) | 287, 355, 372, 491 | 637 | 5.59 | 3.49 | 2.10 |
| compound (2) | 249, 286, 371, 487 | 638 | 5.62 | 3.52 | 2.10 |
| compound (3) | 253, 288, 374, 441, | 634 | 5.58 | 3.44 | 2.14 |
| | 492 | | | | |
| compound (4) | 251, 273, 288, 372, | 641 | 5.58 | 3.37 | 2.11 |
| | 439, 493 | | | | |
| compound (5) | 270, 289, 379, 490 | 628 | 5.56 | 3.40 | 2.16 |
| compound (6) | 268, 287, 379, 492 | 629 | 5.62 | 3.45 | 2.17 |
| compound (7) | 253, 289, 372, 433, | 634 | 5.47 | 3.35 | 2.14 |
| | 492 | | | | |
| compound (8) | 277, 305, 368, 474, | 616 | 5.35 | 3.15 | 2.20 |
| | 511 | | | | |
| compound (9) | 280, 305, 366, 472, | 619 | 5.32 | 3.13 | 2.19 |
| | 512 | | | | |
| compound (10) | 343, 394, 460, 505 | 603 | 5.36 | 3.12 | 2.24 |
| compound (11) | 296, 337, 396, 458, | 602 | 5.43 | 3.20 | 2.23 |
| | 510 | | | | |
| compound (12) | 339, 395, 461, 507 | 601 | 5.44 | 3.20 | 2.24 |
| compound (13) | 252, 272, 359, 370, | 644 | 5.51 | 3.41 | 2.10 |
| | 439, 495 | | | | |

### Example 14

### Device Utilizing Compound (1)

A light-emitting device utilizing the compound (1) of this example is shown in FIG. 4. The light-emission layer 3 is formed by doping the compound (1) into the light-emission host material. The light-emitting device further comprises the anode 1, cathode 2, hole-transport layer 4, electron-transport layer 5, hole-blocker layer 6, and electron-injection layer 8. The film composition of Examples 14-1 to 14-5 is shown in Table 2. In Table 2, the concentration of the compound (1) doped in the host material is represented with %. In Example 14-4, TCTA in the hole-transport layer 4 can be referred to as an “electron-blocker layer”. In Example 14-5, TPBI in the hole-blocker layer 6 may function as an electron-transport layer. FIGS. 6-1 to 6-4 show spectrograms of the photoluminescence (PL) of the light-emitting device of Examples 14-1 to 14-5 respectively. The optical and electric properties of the devices are shown in Table 3. In Table 3, ηₑₓₜ represents the external quantum efficiency; L represents the brightness; η_{c} represents the current efficiency; ηₚ represents the power efficiency; λₑₘ represents the emission wavelength; and CIE represents the chromaticity coordinate.

TABLE 2
Film composition of light-emitting device

| | Example 14-1 | Example 14-2 | Example 14-3 | Example 14-4 | Example 14-5 |
|---|---|---|---|---|---|
| anode 1 | ITO glass | ITO glass | ITO glass | ITO glass | |
| hole-transport | NPB | NPB | TCTA | NPB | NPB |
| layer 4 | (30 nm) | (30 nm) | (30 nm) | (close to anode 1) | (30 nm) |
| | | | | (10 nm) + TCTA | |
| | | | | (far from anode 1) | |
| | | | | (20 nm) | |
| light-emission | CBP: 7% | APOA: 7% | CBP: 7% | APOA: 5% | APOA: 6% |
| layer 3 | compound (1) | compound (1) | compound (1) | compound (1) | compound (1) |
| (hos: guest) | (30 nm) | (30 nm) | (30 nm) | (30 nm) | (30 nm) |
| hole-blocker | BCP | BCP | BCP | BCP | TPBI |
| layer 6 | (10 nm) | (10 nm) | (10 nm) | (10 nm) | (500 nm) |
| electron-trans | Alq | Alq | Alq | Alq | |
| port layer 5 | (40 nm) | (40 nm) | (40 nm) | (50 nm) | |
| electron-inject | LiF | LiF | LiF | LiF | LiF |
| ion layer 8 | (1 nm) | (1 nm) | (1 nm) | (1 nm) | (1 nm) |
| cathode 2 | Al | Al | Al | Al | Al |
| | (100 nm) | (100 nm) | (100 nm) | (100 nm) | (100 nm) |

TABLE 3
The optical and electric properties of light-emitting device

| | | Example | Example | Example | Example | Example |
|---|---|---|---|---|---|---|
| | | 14-1 | 14-2 | 14-3 | 14-4 | 14-5 |
| turn-on voltage | [V] | 3.9 | 3.1 | 5 | 2.8 | 2.6 |
| ηₑₓₜ | [%, V] | 11.4, 5.5 | 9.7, 5.5 | 7.9, 9 | 8.9, 3.5 | 6.6, 3.5 |
| L | [cd m⁻², V] | 16166, 15 | 7757, 14.5 | 13856, 16 | 11574, 11.5 | 11393, 11.5 |
| η_{c} | [cd A⁻¹, V] | 9.2, 5.5 | 7.9, 5.5 | 6.1, 9 | 7.8, 3.5 | 6.1, 3.5 |
| ηₚ | [lm W⁻¹, V] | 6.4, 4 | 4.9, 5 | 2.2, 8.5 | 7.6, 3 | 5.5, 3 |
| λₑₘ | [nm] | 636 | 635 | 638 | 634 | 630 |
| CIE, 8V | (x, y) | (0.68, 0.31) | (0.68, 0.31) | (0.68, 0.31) | (0.68, 0.31) | (0.67, 0.31) |

### Example 15

### Device Utilizing Compound (2)

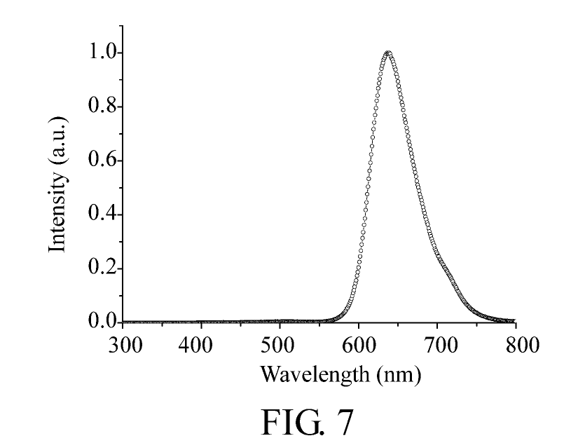

A light-emitting device utilizing the compound (2) of this example is shown in FIG. 4. The light-emitting device has the light-emission layer 3 comprising the compound (2) and disposed between the anode 1 and cathode 2. The light-emission layer 3 is formed by doping the compound (2) into the light-emission host material. The light-emitting device further comprises the hole-transport layer 4, light-emission layer 3, hole-blocker layer 6, electron-transport layer 5 and electron-injection layer 8 sequentially disposed on the anode 1. The film composition of Example 15 is shown in Table 4. In Table 4, the compound (2) concentration of the light-emission layer 3 is represented with %. FIG. 7 shows a spectrogram of the photoluminescence (PL) of the light-emitting device of Example 15. The optical and electric property of the device is shown in Table 5. In Table 5, ηₑₓₜ represents the external quantum efficiency; L represents the brightness; η_{c} represents the current efficiency; ηₚ represents the power efficiency; λₑₘ represents the emission wavelength; and CIE represents the chromaticity coordinate.

TABLE 4
Film composition of light-emitting device

| | Example 15 |
|---|---|
| anode 1 | ITO glass |
| hole-transport layer 4 | NPB (30 nm) |
| light-emission layer 3 | CBP: 7% compound (2) (30 nm) |
| (host: guest) | |
| hole-blocker layer 6 | BCP (10 nm) |
| electron-transport layer 5 | Alq (40 nm) |
| electron-injection layer 8 | LiF (1 nm) |
| cathode 2 | Al (100 nm) |

TABLE 5
The optical and electric properties of light-emitting device

| | Example 15 |
|---|---|
| turn-on voltage [V] | 3.5 |
| ηₑₓₜ [%, V] | 10.4, 5.0 |
| L [cd m⁻², V] | 13291, 16 |
| η_{c} [cd A⁻¹, V] | 8.1, 5.0 |
| ηₚ [lm W⁻¹, V] | 6.1, 4.0 |
| λₑₘ [nm] | 639 |
| CIE, 8 V (x, y) | (0.68, 0.31) |

### Example 16

### Device Utilizing Compound (8)

A light-emitting device utilizing the compound (8) of this example is shown in FIG. 4. The light-emitting device has the light-emission layer 3 comprising the compound (8) and disposed between the anode 1 and cathode 2. The light-emission layer 3 is formed by doping the compound (8) into the light-emission host material. The light-emitting device further comprises the hole-transport layer 4, light-emission layer 3, hole-blocker layer 6, electron-transport layer 5 and electron-injection layer 8 sequentially disposed on the anode 1. The film compositions of Examples 16-1 to 16-2 are shown in Table 6. In Table 6, in the light-emitting layer 3, the concentration of the compound (8) doped in the host material is represented with %. In Example 16-2, TCTA in the hole-transport layer 4 can be referred to as an “electron-blocker layer”. FIGS. 8-1 to 8-2 show spectrograms of the photoluminescence (PL) of the light-emitting devices of Examples 16-1 to 16-2 respectively. The optical and electric properties of the devices are shown in Table 7. In Table 7, ηₑₓₜ represents the external quantum efficiency; L represents the brightness; η_{c} represents the current efficiency; ηₚ represents the power efficiency; λₑₘ represents the emission wavelength; and CIE represents the chromaticity coordinate.

TABLE 6
Film composition of light-emitting device

| | Example 16-1 | Example 16-2 |
|---|---|---|
| anode 1 | ITO glass | ITO glass |
| hole-transport layer 4 | NPB (close to anode 1) (30 nm) + | NPB (close to anode 1) (30 nm) + |
| | NPB: 6% compound (8) | TCTA (far from anode 1) (10 nm) |
| | (far from anode 1) (10 nm) | |
| light-emission layer 3 | CBP: 6% compound (8) (30 nm) | CBP: 6% compound(8) (30 nm) |
| (host: guest) | | |
| hole-blocker layer 6 | BCP (15 nm) | BCP (15 nm) |
| electron-transport layer 5 | Alq (40 nm) | Alq (40 nm) |
| electron-injection layer 8 | LiF (1 nm) | LiF (1 nm) |
| cathode 2 | Al (100 nm) | Al (100 nm) |

TABLE 7
The optical and electric properties of light-emitting device

| | Example 16-1 | Example 16-2 |
|---|---|---|
| turn-on voltage [V] | 3.6 | 3.9 |
| ηₑₓₜ [%, V] | 7.5, 4.5 | 8.0, 4.5 |
| L [cd m⁻², V] | 14350, 13.5 | 13920, 13.5 |
| η_{c} [cd A⁻¹, V] | 10.3, 4.5 | 11.5, 4.5 |
| ηₚ [lm W⁻¹, V] | 7.8, 4.0 | 9.0, 4.0 |
| λₑₘ [nm] | 617 | 617 |
| CIE, 8 V (x, y) | (0.57, 0.31) | (0.62, 0.33) |

### Example 17

### Device Utilizing Compound (9)

A light-emitting device utilizing the compound (9) of this example is shown in FIG. 4. The light-emitting device has the light-emission layer 3 comprising the compound (9) and disposed between the anode 1 and cathode 2. The light-emitting device further comprises the hole-transport layer 4, light-emission layer 3, hole-blocker layer 6, electron-transport layer 5 and electron-injection layer 8 sequentially disposed on the anode 1. The film compositions of Examples 17-1 to 17-2 are shown in Table 8. In Table 8, in the light-emitting layer 3, the concentration of the compound (9) doped in the host material is represented with %. FIGS. 9-1 to 9-2 show spectrograms of the photoluminescence (PL) of the light-emitting devices of Examples 17-1 to 17-2 respectively. The optical and electric properties of the devices are shown in Table 9. In Table 9, ηₑₓₜ represents the external quantum efficiency; L represents the brightness; η_{c} represents the current efficiency; ηₚ represents the power efficiency; λₑₘ represents the emission wavelength; and CIE represents the chromaticity coordinate.

TABLE 8
Film composition of light-emitting device

| | Example 17-1 | Example 17-2 |
|---|---|---|
| anode 1 | ITO glass | ITO glass |
| hole-transport layer 4 | TCTA (40 nm) | NPB (40 nm) |
| light-emission layer 3 | CBP: 6% compound | CBP: 6% compound |
| (host: guest) | (9) (30 nm) | (9) (30 nm) |
| hole-blocker layer 6 | TPBI (15 nm) | BCP (15 nm) |
| electron-transport layer 5 | Alq (40 nm) | Alq (40 nm) |
| electron-injection layer 8 | LiF (1 nm) | LiF (1 nm) |
| cathode 2 | Al (100 nm) | Al (100 nm) |

TABLE 9
The optical and electric properties of light-emitting device

| | Example 17-1 | Example 17-2 |
|---|---|---|
| turn-on voltage [V] | 3.6 | 4 |
| ηₑₓₜ [%, V] | 5.9, 5.0 | 8.6, 5.5 |
| L [cd m⁻², V] | 13532, 18.5 | 17861, 14 |
| η_{c} [cd A⁻¹, V] | 7.1, 5.0 | 9.8, 5.5 |
| ηₚ [lm W⁻¹, V] | 5.3, 4.0 | 6.9, 4.0 |
| λₑₘ [nm] | 622 | 623 |
| CIE, 8 V (x, y) | (0.67, 0.32) | (0.67, 0.32) |

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organometallic complex, having Formula (I): 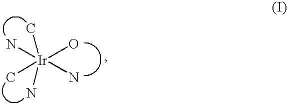
wherein each of N̂C bidentate ligands independently is: 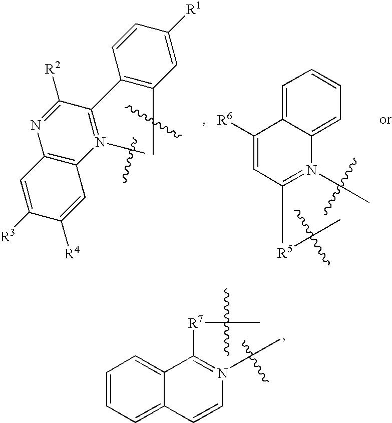
a N̂O bidentate ligand is: 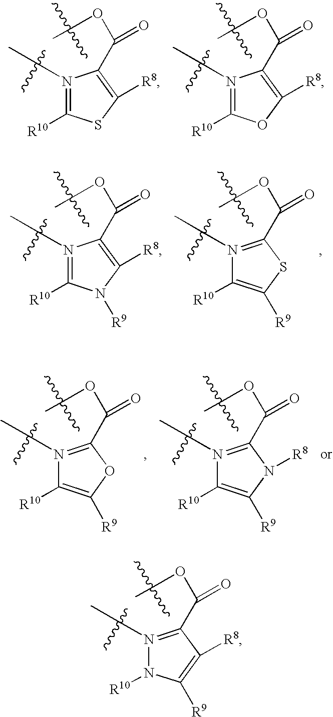
R¹ to R¹⁰ each independently are H, alkyl, alkenyl, alkynyl, CN, CF₃, alkylamino, amino, alkoxy, halo, aryl, or heteroaryl.

2. The organometallic complex as claimed in claim 1, wherein R¹ is H or F.

3. The organometallic complex as claimed in claim 1, wherein R³ and R⁴ are the same.

4. The organometallic complex as claimed in claim 1, wherein each of the N̂C bidentate ligands is:

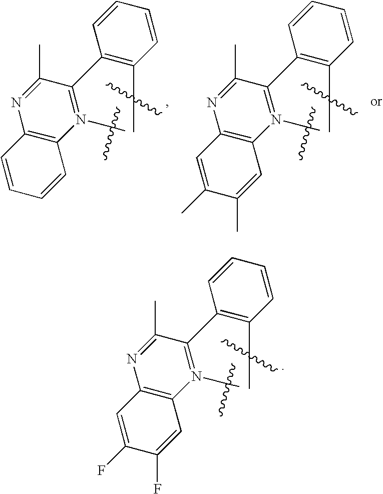

5. The organometallic complex as claimed in claim 1, wherein each of the N̂C bidentate ligands is:

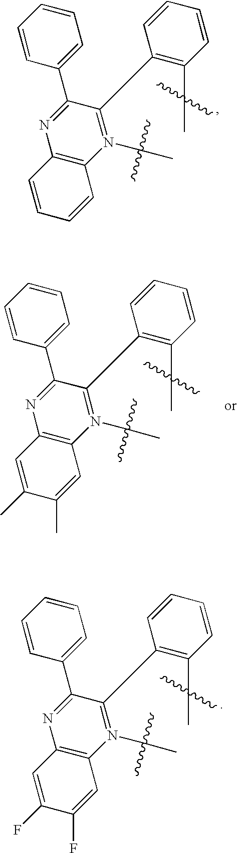

6. The organometallic complex as claimed in claim 1, wherein each of the N̂C bidentate ligands is:

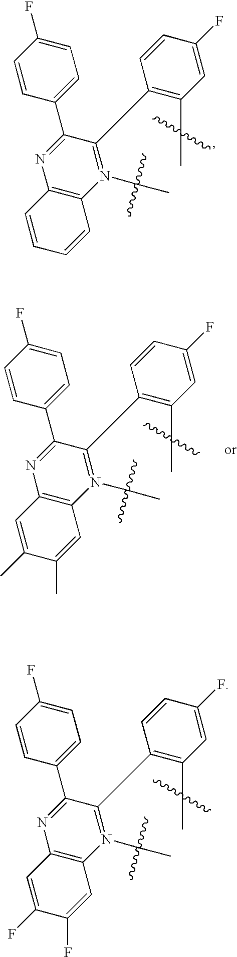

7. The organometallic complex as claimed in claim 1, wherein each of the N̂C bidentate ligands is:

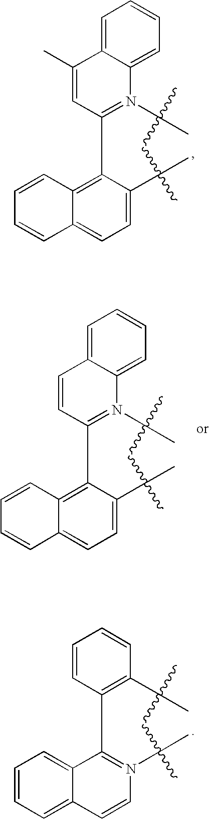

8. The organometallic complex as claimed in claim 1, wherein the N̂O bidentate ligand is:

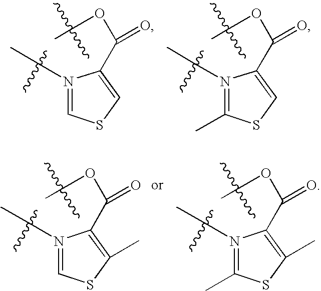

9. The organometallic complex as claimed in claim 1, wherein the N̂O bidentate ligand is:

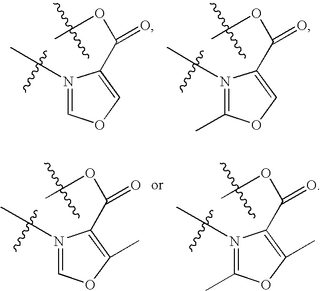

10. The organometallic complex as claimed in claim 1, wherein the N̂O bidentate ligand is:

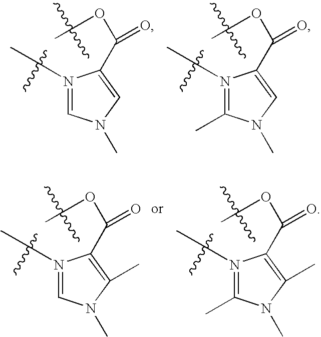

11. The organometallic complex as claimed in claim 1, wherein the N̂O bidentate ligand is:

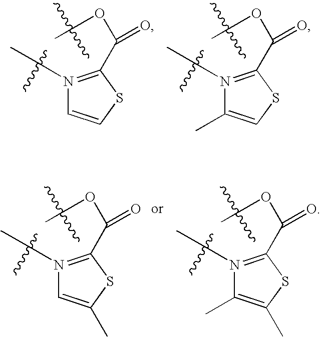

12. The organometallic complex as claimed in claim 1, wherein the N̂O bidentate ligand is:

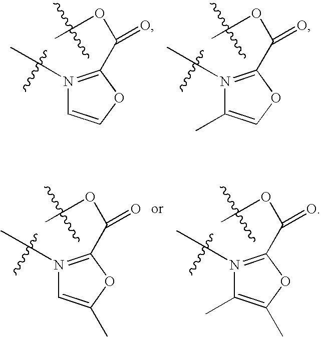

13. The organometallic complex as claimed in claim 1, wherein the N̂O bidentate ligand is:

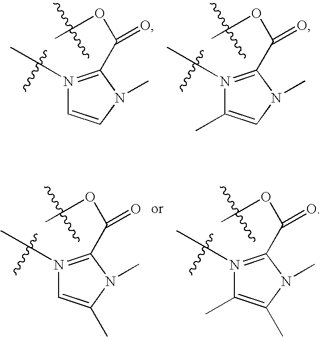

14. The organometallic complex as claimed in claim 1, wherein the N̂O bidentate ligand is:

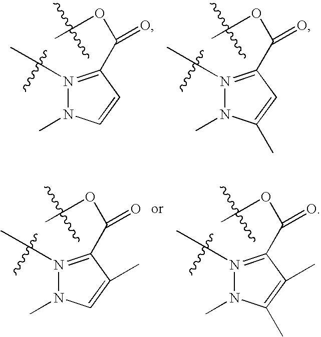

15. The organometallic complex as claimed in claim 1 is used as a light-emission material of an organic light-emitting diode.

16. The organometallic complex as claimed in claim 15 is a red phosphorescent material.

17. An organic light-emitting diode, comprising:
a cathode and an anode; and
a light-emission layer including the organometallic complex as claimed in claim 1 and disposed between the cathode and anode.

18. The organic light-emitting diode as claimed in claim 17, wherein the organic light-emitting diode is a red phosphorescent organic light-emitting diode.

19. The organic light-emitting diode as claimed in claim 17, wherein the organometallic complex is used as a dopant of the light-emission layer.

20. The organic light-emitting diode as claimed in claim 17, further comprising a hole-transporting layer between the light-emission layer and the anode.

21. The organic light-emitting diode as claimed in claim 17, further comprising an electron-transporting layer between the light-emission layer and the cathode.

22. The organic light-emitting diode as claimed in claim 17, further comprising a hole-blocker layer between the light-emission layer and the cathode.

23. The organic light-emitting diode as claimed in claim 17, further comprising an electron-blocker layer between the light-emission layer and the anode.

24. The organic light-emitting diode as claimed in claim 17, further comprising an electron-injecting layer between the light-emission layer and the cathode.
